(19) United States
(12) Patent Application Publication
(10) Pub. No.: US 2026/0090060 A1
(43) Pub. Date: Mar. 26, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Pin-Wen CHEN, Keelung City (TW); Li-Wei CHU, New Taipei City (TW); Chih-Chieh LEE, Taipei City (TW); Hung-Chang HSU, Kaohsiung (TW); Wei-Jung LIN, Hsinchu City (TW); Chih-Wei CHANG, Hsin-Chu (TW); Ming-Hsing TSAI, Chu-Pei City (TW)

(21) Appl. No.: 19/011,985

(22) Filed: Jan. 7, 2025

Related U.S. Application Data
(60) Provisional application No. 63/698,642, filed on Sep. 25, 2024.

(51) Int. Cl. H10D 64/23; H10D 30/00; H10D 30/01; H10D 30/43; H10D 62/10; H10D 84/01; H10D 84/83

(52) U.S. Cl. CPC H10D 64/258; H10D 30/014; H10D 30/019; H10D 30/43; H10D 30/507; H10D 62/121; H10D 84/0128; H10D 84/013; H10D 84/832

(57) ABSTRACT

A source/drain contact of a nanostructure transistor is formed such that the source/drain contact is recessed within an underlying source/drain region of the nanostructure transistor using a multiple-step etching process. The source/drain contact being recessed within the source/drain region provides a greater amount of surface area for the source/drain contact to contact the source/drain region. This provides for increased contact surface area between the source/drain contact and the source/drain region, and the increased contact surface area provides for reduced contact resistance between the source/drain region and the source/drain contact, because of the less-restricted current flow path between the source/drain region and the source/drain contact. In this way, the reduced contact resistance between the source/drain region and the source/drain contact enables a greater power efficiency to be achieved for the nanostructure transistor and/or enables increased switching speeds to be achieved for the nanostructure transistor, among other examples.

### CROSS-REFERENCE TO RELATED APPLICATION

This Patent Application claims priority to U.S. Provisional Patent Application No. 63/698,642 , filed on Sep. 25, 2024, and entitled “SEMICONDUCTOR DEVICE AND METHODS OF FORMATION.” The disclosure of the prior Application is considered part of and is incorporated by reference into this Patent Application.

### BACKGROUND

As semiconductor device manufacturing advances and technology processing nodes decrease in size, transistors may become affected by short channel effects (SCEs) such as hot carrier degradation, barrier lowering, and quantum confinement, among other examples. In addition, as the gate length of a transistor is reduced for smaller technology nodes, source/drain (S/D) electron tunneling increases, which increases the off current for the transistor (the current that flows through the channel of the transistor when the transistor is in an off configuration). Silicon (Si)/silicon germanium (SiGe) nanostructure transistors such as nanowires, nanosheets, and gate-all-around (GAA) devices are potential candidates to overcome short channel effects at smaller technology nodes. Nanostructure transistors are efficient structures that may experience reduced SCEs and enhanced carrier mobility relative to other types of transistors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C are diagrams of an example implementation of a fin definition process described herein.

FIG. 2 is a diagram of an example dummy gate structure formation process described herein.

FIG. 3 is a diagram of an example implementation of a source/drain recess formation process described herein.

FIGS. 4A and 4B are diagrams of an example implementation of an inner spacer formation process described herein.

FIGS. 5A and 5B are diagrams of an example implementation of a source/drain region formation process described herein.

FIG. 6 is a diagram of an example implementation of an interlayer dielectric formation process described herein.

FIGS. 7A and 7B are diagrams of an example implementation of a replacement gate process described herein.

FIGS. 8A-8G are diagrams of an example implementation of a source/drain contact formation process described herein.

FIG. 9 is a diagram of an example implementation of the semiconductor device described herein.

FIG. 10 is a diagram of an example implementation of the semiconductor device described herein.

FIG. 11 is a diagram of an example implementation of the semiconductor device described herein.

FIG. 12 is a flowchart of an example process associated with forming a semiconductor device described herein.

FIG. 13 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Nanostructure transistors (e.g., nanowire transistors, nanosheet transistors, GAA transistors, multi-bridge channel transistors, nanoribbon transistors, and/or other types of nanostructure transistors) may overcome one or more of the above-described drawbacks of some types of transistors. However, nanostructure transistors face fabrication challenges that can cause performance issues, manufacturing yield issues, and/or device failures.

For example, various parts of a nanostructure transistor may be susceptible to increased resistance as feature sizes are reduced. One such part of a nanostructure transistor that is susceptible to increased resistance is the connection between a source/drain region of the nanostructure transistor and a source/drain contact formed on the source/drain region. As the sizes (e.g., the lateral widths) of the source/drain region and the source/drain contact are reduced, the contact surface area between the source/drain region and the source/drain contact is reduced. The reduced contact surface area between the source/drain region and the source/drain contact restricts the flow of electrons between the source/drain region and the source/drain contact, which increases current crowding around the source/drain region and the source/drain contact. The increased current crowding results in increased contact resistance between the source/drain region and the source/drain contact. This can lead to reduced power efficiency for the nanostructure transistor and/or reduced switching speeds for the nanostructure transistor, among other examples.

In some implementations described herein, a source/drain contact of a nanostructure transistor is formed such that the source/drain contact is recessed within an underlying source/drain region of the nanostructure transistor. A multiple-step etch process may be performed to form a recess in the source/drain region such that the recess at least extends below the top-most nanostructure channel of the nanostructure transistor. In some implementations, the recess may be formed in the source/drain region such that the recess extends below a middle nanostructure channel and/or extends to a depth of a bottom-most nanostructure channel of the nanostructure transistor.

The increased depth of the recess (e.g., relative to performing a single etch operation to form the recess to a depth of the first nanostructure channel) provides a greater amount of surface area for the source/drain contact (e.g., that is formed in the recess) to contact the source/drain region. This provides for increased contact surface area between the source/drain contact and the source/drain region, and the increased contact surface area provides for reduced contact resistance between the source/drain region and the source/drain contact, because of the less-restricted current flow path between the source/drain region and the source/drain contact. In this way, the reduced contact resistance between the source/drain region and the source/drain contact enables a greater power efficiency to be achieved for the nanostructure transistor and/or enables increased switching speeds to be achieved for the nanostructure transistor, among other examples.

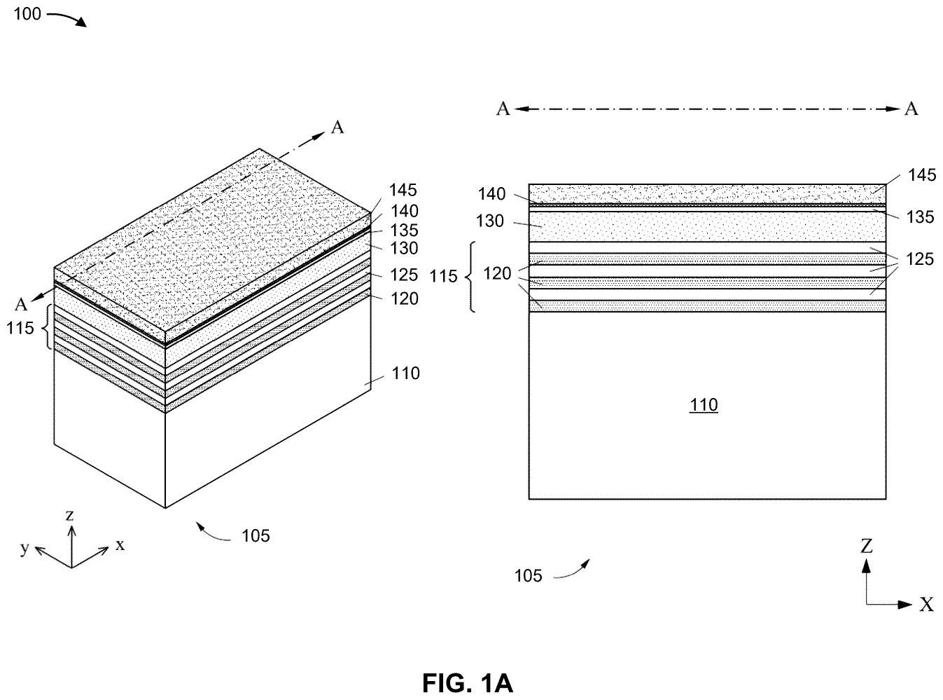

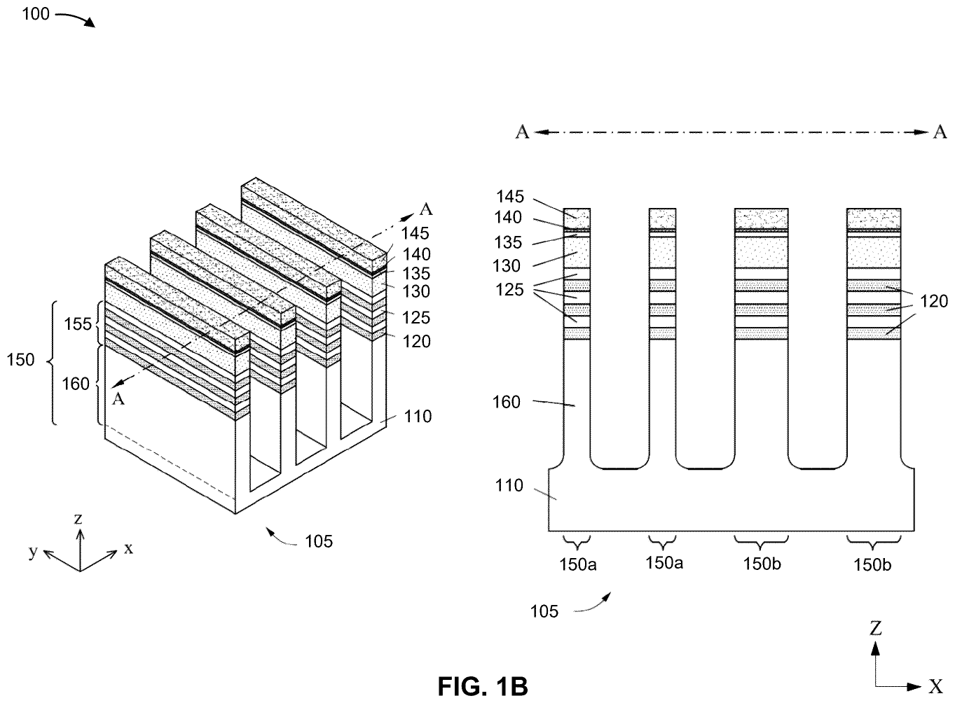

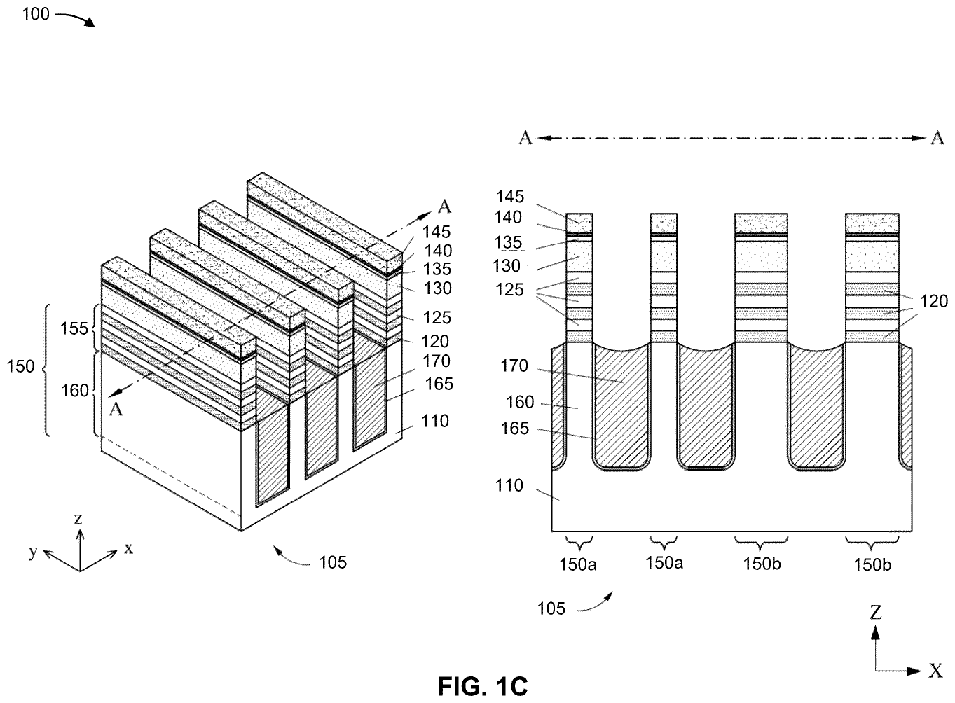

FIGS. 1A-1C are diagrams of an example implementation 100 of a fin definition process described herein. The example implementation 100 includes an example of forming fin structures and associated shallow trench isolation (STI) regions for a semiconductor device 105 described herein. The semiconductor device 105 may be manufactured to include one or more transistors. The one or more transistors may include nanostructure transistor(s) such as nanowire transistors, nanosheet transistors, gate-all-around (GAA) transistors, multi-bridge channel transistors, nanoribbon transistors, and/or other types of nanostructure transistors. The example implementation 100 includes an example of forming the fin structures and the associated STI regions for the transistors of the semiconductor device 105.

FIGS. 1A-1C each illustrate a perspective view of the semiconductor device 105 and a cross-sectional view along the line A-A in the perspective view. As shown in FIG. 1A, processing of the semiconductor device 105 is performed in connection with a semiconductor substrate 110. The semiconductor substrate 110 includes a silicon (Si) substrate, a substrate formed of a material including silicon, a III-V compound semiconductor material substrate such as gallium arsenide (GaAs), a silicon on insulator (SOI) substrate, a germanium (Ge) substrate, a silicon germanium (SiGe) substrate, a silicon carbide (SiC) substrate, or another type of semiconductor substrate.

A layer stack 115 is formed on the semiconductor substrate 110. The layer stack 115 may be referred to as a superlattice. The layer stack 115 includes a plurality of alternating layers that are arranged in a direction (e.g., the z-direction) that is approximately perpendicular to the semiconductor substrate 110. For example, the layer stack 115 includes vertically alternating layers of sacrificial nanostructure layers 120 and nanostructure channel layers 125 above the semiconductor substrate 110. The quantity of the sacrificial nanostructure layers 120 and the quantity of the nanostructure channel layers 125 illustrated in FIG. 1A are examples, and other quantities of the sacrificial nanostructure layers 120 and the nanostructure channel layers 125 are within the scope of the present disclosure.

The sacrificial nanostructure layers 120 enable a vertical distance to be defined between adjacent nanostructure channels that are formed from the nanostructure channel layers 125, and serve as placeholder layers for subsequently-formed gate structures of the transistors of the semiconductor device 105 that are formed around the nanostructure channels. The sacrificial nanostructure layers 120 include a first material composition, and the nanostructure channel layers 125 include a second material composition. In some implementations, the first material composition and the second material composition are the same material composition. In some implementations, the first material composition and the second material composition are different material compositions. As an example, the sacrificial nanostructure layers 120 may include silicon germanium (SiGe) and the nanostructure channel layers 125 may include silicon (Si). This enables the sacrificial nanostructure layers 120 and/or the nanostructure channel layers 125 to be selectively etched (e.g., enables the sacrificial nanostructure layers 120 and not the nanostructure channel layers 125 to be etched, enables the nanostructure channel layers 125 and not the sacrificial nanostructure layers 120 to be etched) depending on the type of etchant that is used.

One or more types of deposition tools may be used to deposit and/or grow the alternating layers of the layer stack 115 to include nanostructures (e.g., nanosheets) on the semiconductor substrate 110. For example, a deposition tool may be used to grow the sacrificial nanostructure layers 120 and/or the nanostructure channel layers 125 by epitaxial growth, which may include epitaxy techniques such as a molecular beam epitaxy (MBE), metalorganic chemical vapor deposition (MOCVD) process, and/or another suitable epitaxy technique. Additionally and/or alternatively, the sacrificial nanostructure layers 120 and/or the nanostructure channel layers 125 may be deposited by chemical vapor deposition (CVD), physical vapor deposition (PVD), atomic layer deposition (ALD), and/or another suitable deposition technique.

One or more masking layers may be form (e.g., using one or more deposition tools) on the layer stack 115. The masking layer(s) may include a hard mask (HM) layer 130, a capping layer 135, an oxide layer 140, and/or a nitride layer 145. Masking layer(s) may be used to perform a fin patterning operation to form fin structures in the semiconductor substrate 110.

As shown in FIG. 1B, the layer stack 115 and the semiconductor substrate 110 are etched to remove portions of the layer stack 115 and portions of the semiconductor substrate 110. This results in formation of fin structures 150 that extend above the semiconductor substrate 110. The fin structures 150 may extend in a y-direction in the semiconductor device 105 and may be arranged in an x-direction in the semiconductor device 105. A fin structure 150 includes a portion 155 of the layer stack 115 over and/or on a fin portion 160 above the semiconductor substrate 110. The fin structures 150 may be formed by patterning the one or more masking layers and etching the semiconductor substrate 110 based on a pattern formed in one or more of the masking layers. The one or more masking layers may be patterned using photolithography techniques, including double-patterning or multi-patterning techniques. An etch tool may be used to etch the semiconductor substrate 110 based on the pattern using a dry etch technique (e.g., reactive ion etching), a wet etch technique, and/or a combination thereof.

As further shown in FIG. 1B, some fin structures 150 may be formed to have different widths for different types of nanostructure transistors. As an example, a first subset of fin structures 150a may be formed for p-type nanostructure transistors (e.g., p-type metal oxide semiconductor (PMOS) nanostructure transistors), and a second subset of fin structures 150b may be formed for n-type nanostructure transistors (e.g., n-type metal oxide semiconductor (NMOS) nanostructure transistors). As another example, a first subset of fin structures 150a may be formed for nanostructure transistors that are configured to operate at lower voltages, and a second subset of fin structures 150b may be formed for nanostructure transistors that are configured to operate at higher voltages.

As shown in FIG. 1C, a liner 165 and STI regions 170 are formed between adjacent fin portions 160 of the fin structures 150. The liner 165 and the STI regions 170 may each include a dielectric material such as a silicon oxide (SiOₓ), a silicon nitride (SiₓN_{y}), a silicon oxynitride (SiON), fluoride-doped silicate glass (FSG), a low-k dielectric material, and/or another suitable insulating material.

A deposition tool may be used to conformally deposit the liner (e.g., using ALD or another conformal deposition technique), and may deposit a dielectric layer (e.g., using CVD, PVD, a ALD, and/or another suitable deposition technique) on the liner 165 such that the dielectric layer fully fills in the spaces between the fin structures 150 and extends above the tops of the fin structures 150. A planarization tool may then be used to perform a planarization or polishing operation (e.g., a chemical mechanical planarization (CMP) operation) to planarize the dielectric layer such that the top surface of the dielectric layer is approximately co-planar with the top of the nitride layer 145. The nitride layer 145 functions as a CMP stop layer in the planarization operation. An etch tool may be used to then etch the dielectric layer to form the STI regions 170 such that the top surfaces of the STI region 170 are approximately co-planar with or below the bottom-most sacrificial nanostructure layer 120.

As indicated above, FIGS. 1A-1C are provided as an example. Other examples may differ from what is described with regard to FIGS. 1A-1C.

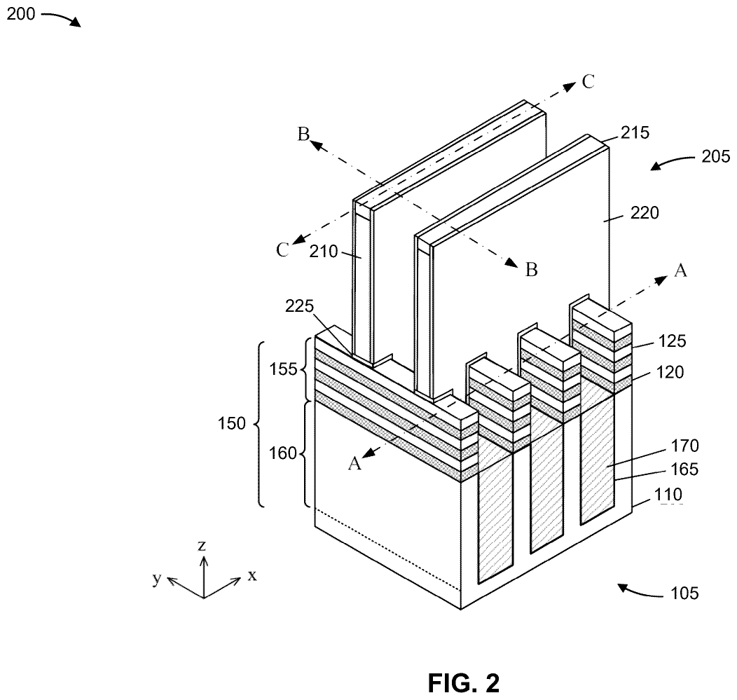

FIG. 2 is a diagram of an example implementation 200 of a dummy gate formation process described herein. The example implementation 200 includes an example of forming dummy gate structures 205 for nanostructure transistors of the semiconductor device 105. In some implementations, the operations described in connection with the example implementation 700 are performed after the processes described in connection with FIGS. 1A-1C.

FIG. 2 illustrates a perspective view of the semiconductor device 105 with the dummy gate structures 205 formed thereon. The dummy gate structures 205 (also referred to as dummy gate stacks or temporary gate structures) are formed over portions of the fin structures 150 and portions of the STI regions 170. The dummy gate structures 205 extend in the x-direction and are arranged in the y-direction such that the dummy gate structures 205 are approximately perpendicular to the fin structures 150. The dummy gate structures 205 are sacrificial structures that are to be replaced by replacement gate structures or replacement gate stacks at a subsequent processing stage for the semiconductor device 105. The dummy gate structures 205 may also be used to define source/drain (S/D) recesses in which source/drain regions of the nanostructure transistors are formed in the fin structures 150.

A dummy gate structure 205 may include a gate electrode layer 210, a hard mask layer 215 over and/or on the gate electrode layer 210, and spacer layers 220 on opposing sides of the gate electrode layer 210, and a gate dielectric layer 225 under the gate electrode layer 210. The gate electrode layer 210 includes polycrystalline silicon (polysilicon or PO) or another material. The hard mask layer 215 includes one or more layers such as an oxide layer (e.g., a pad oxide layer that may include silicon dioxide (SiO₂) or another material) and a nitride layer (e.g., a pad nitride layer that may include a silicon nitride such as Si₃N₄ or another material) formed over the oxide layer. The spacer layers 220 include a silicon oxycarbide (SiOC), a nitrogen free SiOC, or another suitable material. The gate dielectric layer 225 may include a silicon oxide (e.g., SiOₓ such as SiO₂), a silicon nitride (e.g., SiₓN_{y} such as Si₃N₄), a high dielectric constant (high-k) dielectric material (e.g., a dielectric material having a dielectric constant greater than approximately 3.9) and/or another suitable material.

The layers of the dummy gate structures 205 may be formed using various semiconductor processing techniques such depositing the layers of the dummy gate structures 205, patterning the layers of the dummy gate structures 205 to define the dummy gate structures 205, and/or other semiconductor processing techniques.

FIG. 2 further illustrates reference cross-sections that are used in subsequent figures described herein. Cross-section A-A is in an x-z plane (referred to as a y-cut) across the fin structures 150 in the source/drain areas of the semiconductor device 105. Cross-section B-B is in a y-z plane (referred to as an x-cut) perpendicular to the cross-section A-A, and is across the dummy gate structures 205 and along an underlying fin structure 150. Cross-section C-C is in the x-z plane parallel to the cross-section A-A and perpendicular to the cross-section B-B, and is along a dummy gate structure 205. Subsequent figures refer to these reference cross-sections for clarity. In some figures, some reference numbers of components or features illustrated therein may be omitted to avoid obscuring other components or features for ease of depicting the figures.

As indicated above, FIG. 2 is provided as an example. Other examples may differ from what is described with regard to FIG. 2.

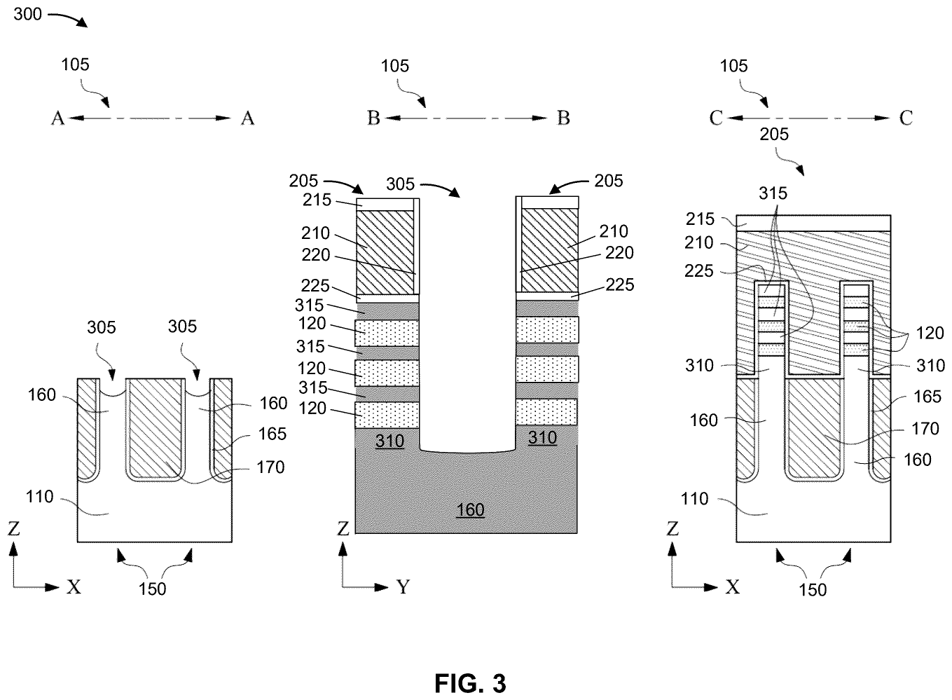

FIG. 3 is a diagrams of an example implementation 300 of a source/drain recess formation process described herein. The example implementation 300 includes an example of forming source/drain recesses 305 for source/drain regions of nanostructure transistors of the semiconductor device 105. FIG. 3 is illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 300 are performed after the processes described in connection with FIGS. 1A-2.

As shown in the cross-sectional plane A-A and cross-sectional plane B-B in FIG. 3, the source/drain recesses 305 are formed through portions 155 of a fin structure 150 in an etch operation. The source/drain recesses 305 are formed on opposing sides of a dummy gate structure 205. The etch operation may be performed using the etch tool and may be referred to a strained source/drain (SSD) etch operation. In some implementations, the etch operation includes the use of a plasma etch technique, a wet chemical etch technique, and/or another type of etch technique.

The source/drain recesses 305 also extend into a portion of the fin portion 160 of the fin structure 150. This results in formation of mesa regions 310 in the fin structure 150. The sidewalls of the portions of each source/drain recess 305 below the layer stack 155 correspond to sidewalls of mesa regions 310. A mesa region 310 (also referred to as pedestals) refers to a region of the fin portion 160 of the fin structure 150 on which nanostructure channels are defined from the nanostructure channel layers 125. The nanostructure channels 315 extend between adjacent source/drain recesses 305 and are located under the dummy gate structure 205 between the adjacent source/drain recesses 305.

The nanostructure channels 315 include silicon-based nanostructures (e.g., nanosheets or nanowires, among other examples) that function as the semiconductive channels of the nanostructure transistors of the semiconductor device 105. In some implementations, the nanostructure channels 315 may include silicon germanium (SiGe) or another silicon-based material. The nanostructure channels 315 are arranged in a direction (e.g., the z-direction) that is approximately perpendicular to the semiconductor substrate 110. In other words, the nanostructure channels 315 are vertically arranged or stacked above the semiconductor substrate 110.

As indicated above, FIG. 3 is provided as an example. Other examples may differ from what is described with regard to FIG. 3.

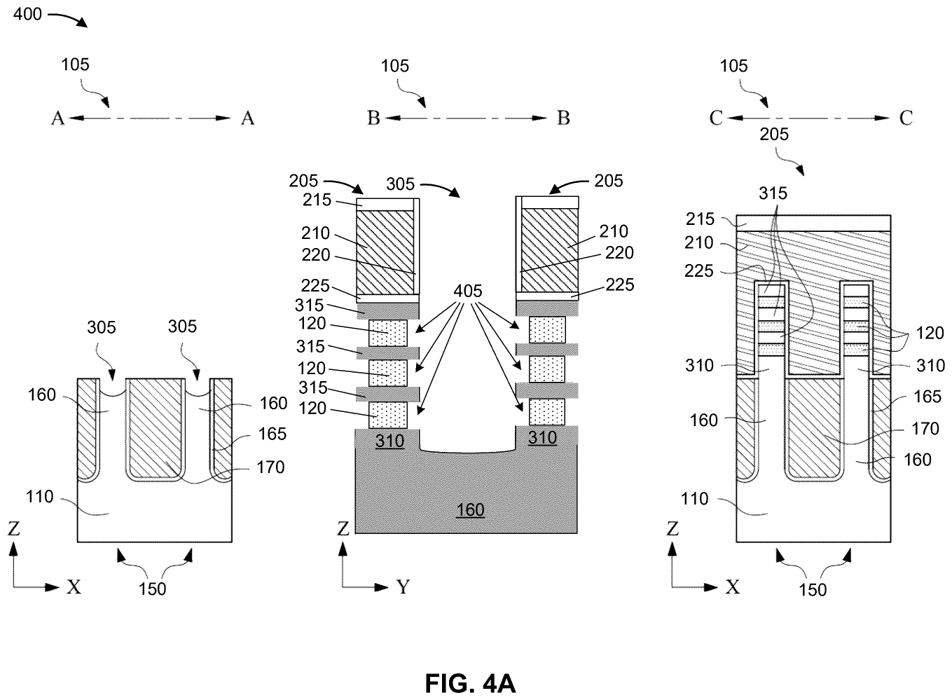

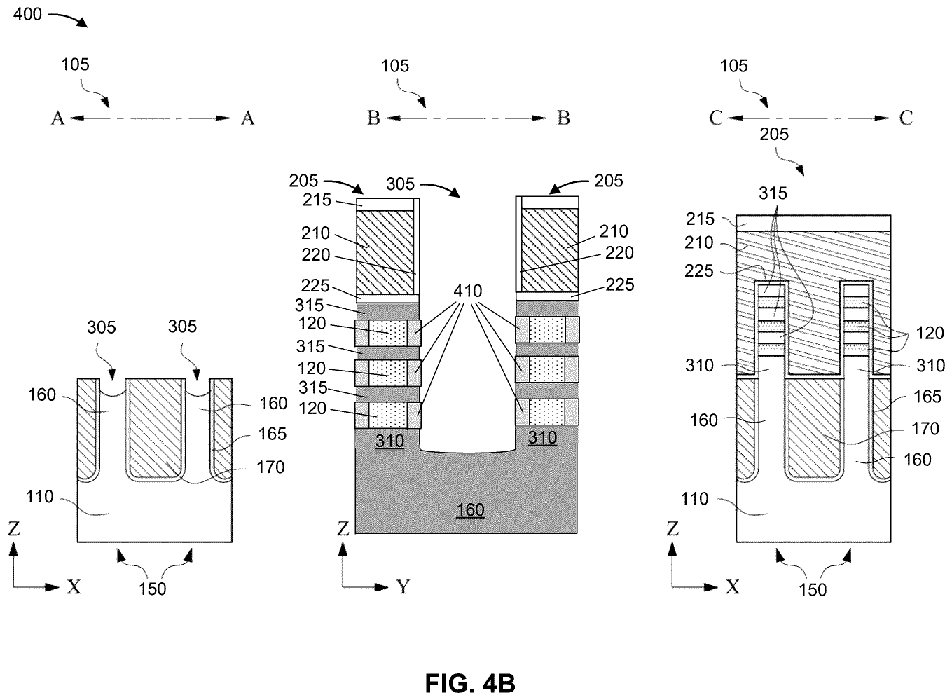

FIGS. 4A and 4B are diagrams of an example implementation 400 of an inner spacer formation process described herein. The example implementation 400 includes an example of forming inner spacers between ends of the nanostructure channels 315 that are exposed in the source/drain recesses 305. FIGS. 4A and 4B are illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 400 are performed after the processes described in connection with FIGS. 1A-3.

As shown in the cross-sectional plane A-A and in the cross-sectional plane B-B in FIG. 4A, the ends of the sacrificial nanostructure layers 120 may be laterally etched (e.g., in the x-direction that is approximately parallel to a length of the sacrificial nanostructure layers 120) in an etch operation, thereby forming cavities 405 between the ends of the nanostructure channels 315 that are exposed in the source/drain recesses 305. An etch tool may be used to perform a wet etch operation to selectively etch the ends of the sacrificial nanostructure layers 120 relative to the nanostructure channels 315 to form the cavities 405. Additionally and/or alternatively, another etch technique may be used, such as dry etching (e.g., gas-based etching).

As shown in the cross-sectional plane A-A and in the cross-sectional plane B-B in FIG. 4B, inner spacers (InSP) 410 are formed in the cavities 405 in the ends of the sacrificial nanostructure layers 120 that are exposed in the source/drain recesses 305. The inner spacers 405 may be included to reduce parasitic capacitance in the nanostructure transistors and to protect source/drain regions (that are subsequently formed in the source/drain recesses 305) from being etched in a nanosheet release operation to remove the sacrificial nanostructure layers 120 between the nanostructure channels 315. The inner spacers 410 include a silicon nitride (SiₓN_{y}), a silicon oxide (SiOₓ), a silicon oxynitride (SiON), a silicon oxycarbide (SiOC), a silicon carbon nitride (SiCN), a silicon oxycarbonnitride (SiOCN), and/or another dielectric material.

To form the inner spacers 410, a deposition tool may be used to deposit a layer of dielectric material in the cavities 405 and along the sidewalls and bottom surface of the source/drain recesses 305. A CVD technique, a PVD technique, and ALD technique, and/or another deposition technique may be used to deposit the layer of dielectric material. An etch tool is used to subsequently remove excess material of the layer of dielectric material from the source/drain recesses such that remaining portions correspond to the inner spacers 410. Alternatively, the inner spacers 410 may be selectively formed on the ends of the sacrificial nanostructure layers 120 using precursors that selectively bond to the material of the sacrificial nanostructure layers 120 and not to the material of the fin portion 160 and the nanostructure channels 315.

As indicated above, FIGS. 4A and 4B are provided as an example. Other examples may differ from what is described with regard to FIGS. 4A and 4B.

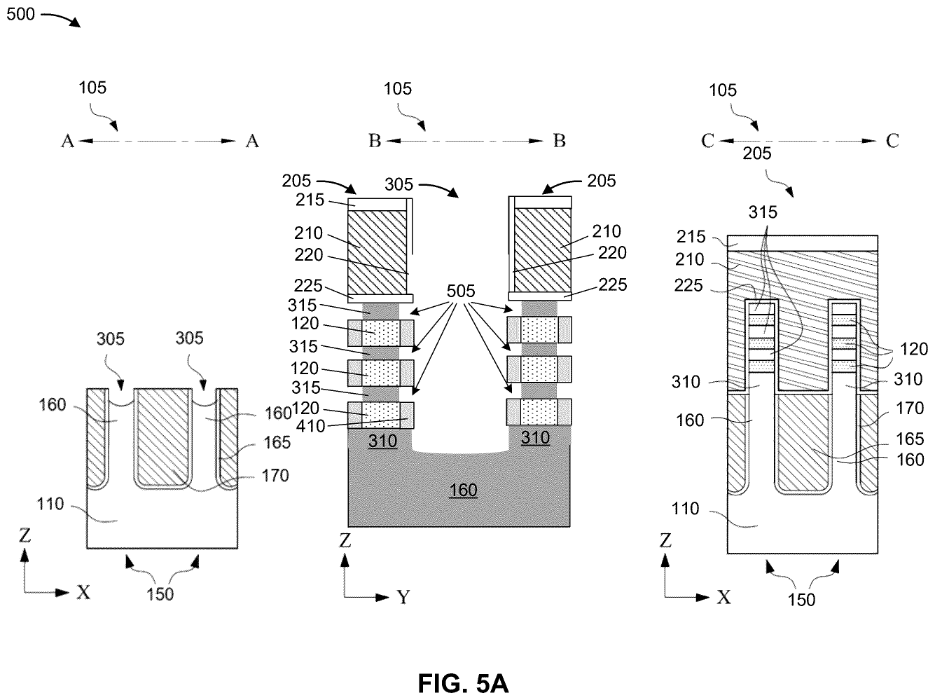

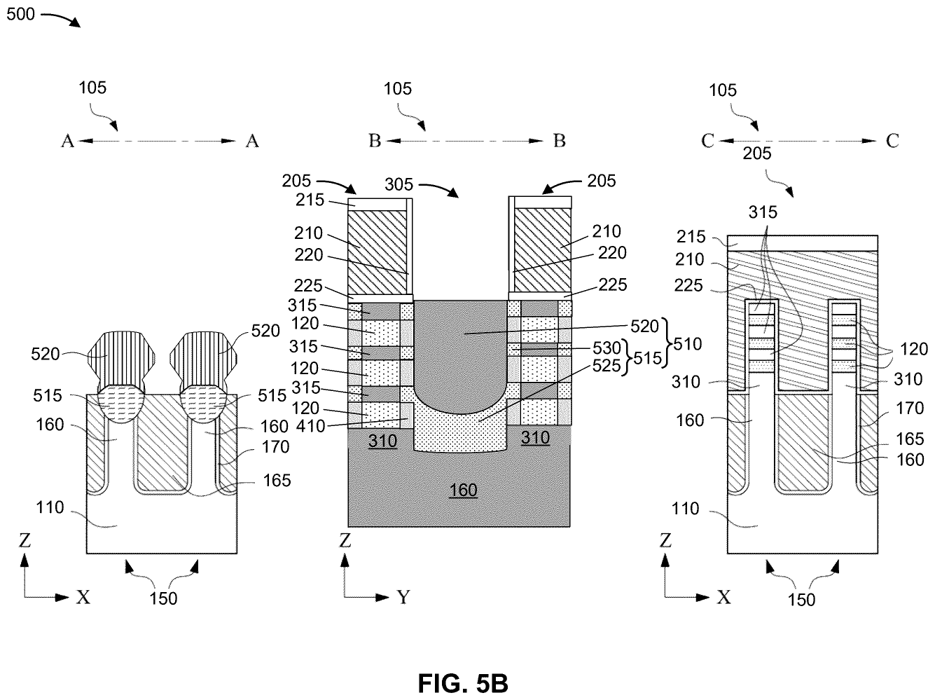

FIGS. 5A and 5B are diagrams of an example implementation 500 of a source/drain region formation process described herein. The example implementation 500 includes an example of forming the source/drain regions of the nanostructure transistors of the semiconductor device 105. FIGS. 5A and 5B are illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 500 are performed after the processes described in connection with FIGS. 1A-4B.

As shown in the cross-sectional plane A-A and in the cross-sectional plane B-B in FIG. 5A, the ends of the nanostructure channels 315 may be laterally etched (e.g., in the x-direction that is approximately parallel to a length of the sacrificial nanostructure layers 120) in an etch operation, thereby forming cavities 505 between vertically adjacent inner spacers 410. An etch tool may be used to perform a wet etch operation to selectively etch the ends of the nanostructure channels 315 relative to the sacrificial nanostructure layers to form the cavities 505. Additionally and/or alternatively, another etch technique may be used, such as dry etching (e.g., gas-based etching).

As shown in the cross-sectional plane A-A and the cross-sectional plane B-B in FIG. 5B, the source/drain recess 305 is filled with one or more layers to form a source/drain region 510 in the source/drain recess 305. For example, a deposition tool may be used to deposit a first epitaxial layer 515 (sometimes referred to as an “L1”) at the bottom of the source/drain recess 305 and on recessed ends of the nanostructure channels 315 in the cavities 505. As another example, a deposition tool may deposit a second epitaxial layer 520 (sometimes referred to as an “L2”) in the source/drain recess 305. The second epitaxial layer 520 may fill in the remaining area in the source/drain recess 305 below the dummy gate structures 205 and may be in contact with the first epitaxial layer 515 and the inner spacers 410 that are still exposed in the source/drain recess 305.

“Source/drain region” may refer to a source or a drain, individually or collectively, depending upon the context. Source/drain regions 510 may be included on opposing sides of a dummy gate structure 205 such that the nanostructure channels 315 under the dummy gate structure 205 extend between, and are electrically coupled to, source/drain regions 510.

The first epitaxial layer 515 and the second epitaxial layer 520 of a source/drain region 510 may each include a semiconductor material such as silicon (Si), silicon germanium (SiGe), silicon arsenide (SiAs), silicon phosphorous (SiP), and/or another semiconductor material. The first epitaxial layer 515 and the second epitaxial layer 520 may each be doped with one or more types of dopants such as arsenic (As), phosphorous (P), and/or boron (B), among other examples.

For a p-type metal-oxide semiconductor (PMOS) nanostructure transistor, the first epitaxial layer 515 and the second epitaxial layer 520 of a source/drain region 510 may each include silicon germanium (SiGe) doped with boron (B). The germanium (Ge) concentration of the second epitaxial layer 520 may be greater than the germanium (Ge) concentration of the first epitaxial layer 515. For example, the germanium (Ge) concentration of the second epitaxial layer 520 may be included in a range of approximately 40% to approximately 60%, whereas the germanium (Ge) concentration of the first epitaxial layer 515 may be included in a range of approximately 10% to approximately 20%. However, other values and ranges are within the scope of the present disclosure. The boron (B) dopant concentration of the second epitaxial layer 520 and the boron (B) dopant concentration of the first epitaxial layer 515 may each be included in a range of approximately 5×10²⁰ to approximately 5×10²¹. However, other values and ranges are within the scope of the present disclosure.

For an n-type metal-oxide semiconductor (NMOS) nanostructure transistor, the first epitaxial layer 515 and the second epitaxial layer 520 of a source/drain region 510 may each include silicon (Si) doped with arsenic (As) and/or phosphorous (P), among other examples. The dopant concentration of the second epitaxial layer 520 may be greater than the dopant concentration of the first epitaxial layer 515. For example, the dopant concentration of the second epitaxial layer 520 may be included in a range of approximately 2×10²¹ to approximately 9×10²¹, whereas the dopant concentration of the first epitaxial layer 515 may be included in a range of approximately 1×10²⁰ to approximately 1×10²¹. However, other values and ranges are within the scope of the present disclosure.

The first epitaxial layer 515 and the second epitaxial layer 520 of a source/drain region 510 may each be epitaxially grown, deposited (e.g., using CVD, PVD, ALD), and/or formed using one or more other deposition techniques. For example, a deposition tool may epitaxially grow merged region 525 of the first epitaxial layer 515 at the bottom of the source/drain recess 305. The merged region 525 may include a continuous layer of epitaxially-grown material that spans from the mesa regions 310 up to the ends of a bottom-most nanostructure channel 315.

As another example, a deposition tool may epitaxially grow a plurality of non-contiguous second epitaxial regions 530 of the first epitaxial layer 515 on the recessed ends of nanostructure channels 315 in the cavities 505 so that the non-contiguous second epitaxial regions 530 are located above the merged region 525. The non-contiguous second epitaxial regions 530 are regions of epitaxially-grown material that are not in contact with each other (e.g., because of being separated by the inner spacers 410), and that are not in contact with the merged region 525. The second epitaxial layer 520 may grow on portions of the inner spacers 410 that are exposed between the non-contiguous second epitaxial regions 530, and between the merged region 525 and the non-contiguous second epitaxial regions 530.

As indicated above, FIGS. 5A and 5B are provided as an example. Other examples may differ from what is described with regard to FIGS. 5A and 5B.

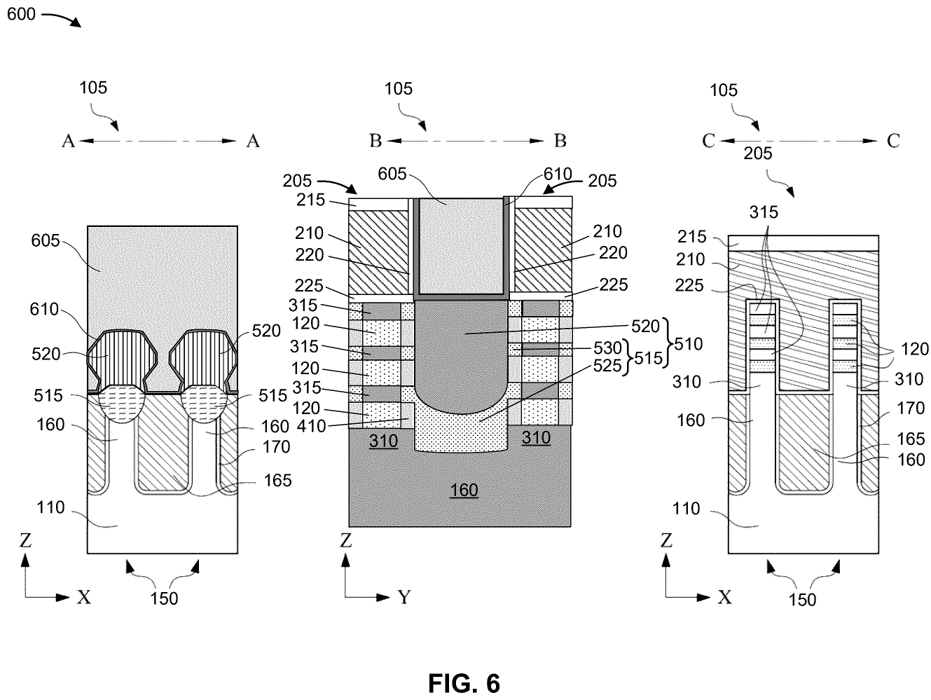

FIG. 6 is a diagram of an example implementation 600 of an interlayer dielectric (ILD) formation process described herein. FIG. 6 is illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 600 are performed after the processes described in connection with FIGS. 1A-5B.

As shown in the cross-sectional plane A-A and the cross-sectional plane B-B in FIG. 6, a dielectric layer 605 is formed over the source/drain regions 510. The dielectric layer 605 (which may be referred to as an ILD layer) fills in areas between the dummy gate structures 205. The dielectric layer 605 is formed to reduce the likelihood of, and/or prevent, damage to the source/drain regions 510 during a replacement gate process to replace the dummy gate structures 205. The dielectric layer 605 may be referred to as an ILD zero (ILDO) layer or another ILD layer.

In some implementations, a contact etch stop layer (CESL) 610 is conformally deposited (e.g., by a deposition tool) over the source/drain regions 510 prior to formation of the dielectric layer 605. The dielectric layer 605 is then formed on the CESL 610. The CESL 610 may provide a mechanism to stop an etch process when forming contacts or vias for the source/drain regions 510.

The dielectric layer 605 may include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, the dielectric layer 605 includes an extreme low dielectric constant (ELK) dielectric material having a dielectric constant that is less than approximately 2.5. Examples of ELK dielectric materials include carbon doped silicon oxide (C—SiOₓ), amorphous fluorinated carbon (a—CₓF_{y}), parylene, bis-benzocyclobutenes (BCB), polytetrafluoroethylene (PTFE), a silicon oxycarbide (SiOC) polymer, porous hydrogen silsesquioxane (HSQ), porous methyl silsesquioxane (MSQ), porous polyarylether (PAE), and/or porous silicon oxide (SiOₓ), among other examples. The dielectric layer 605 may be deposited using a deposition process, such as ALD, CVD, or another deposition technique.

The CESL 610 may be formed of a dielectric material having a different etch selectivity from adjacent layers or components. The CESL 610 may include or may be a nitrogen-containing material, a silicon-containing material, and/or a carbon-containing material. Furthermore, the CESL 610 may include or may be silicon nitride (SiₓN_{y}), silicon carbon nitride (SiCN), carbon nitride (CN), silicon oxynitride (SiON), silicon carbon oxide (SiCO), or a combination thereof, among other examples. The CESL 610 may be deposited using a deposition process, such as ALD, CVD, or another deposition technique.

As indicated above, FIG. 6 is provided as an example. Other examples may differ from what is described with regard to FIG. 6.

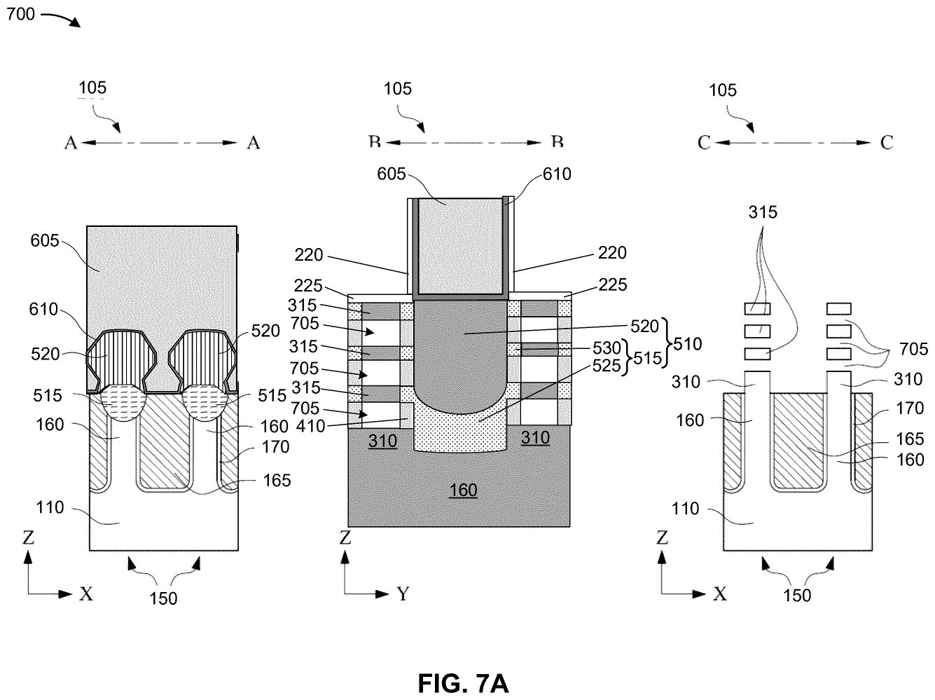

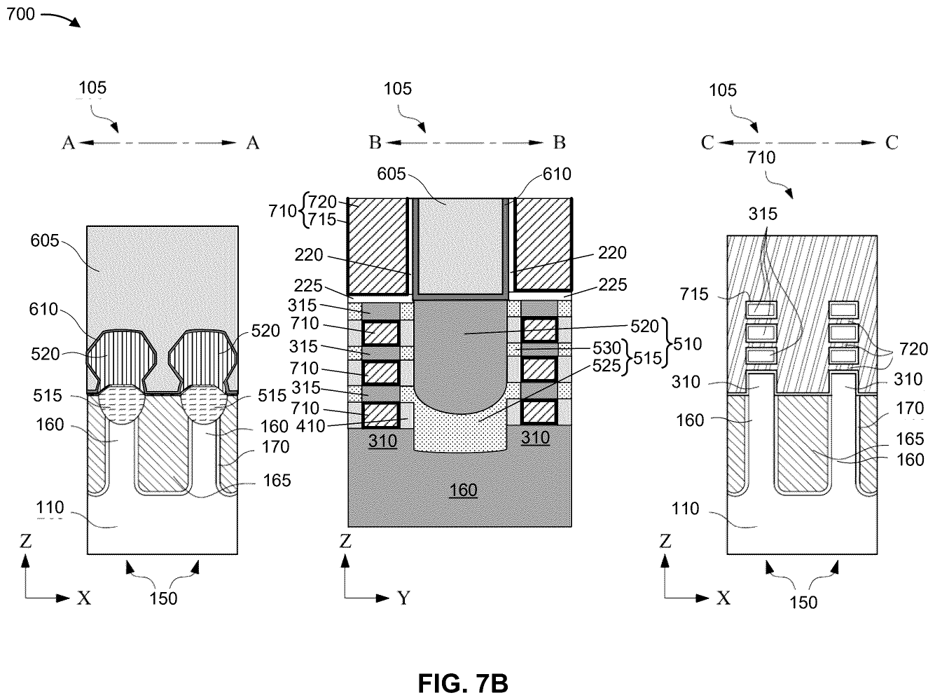

FIGS. 7A and 7B are diagrams of an example implementation 700 of a replacement gate (RPG) process described herein. The example implementation 700 includes an example of a replacement gate process for replacing the dummy gate structures 205 with high-k/metal gate structures (e.g., the replacement gate structures) for the nanostructure transistors of the semiconductor device 105. FIGS. 7A and 7B are each illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 700 are performed after the operations described in connection with FIGS. 1A-6.

As shown in the cross-sectional plane B-B and the cross-sectional plane C-C in FIG. 7A, the replacement gate process includes a dummy gate removal operation. The dummy gate removal operation includes removing the dummy gate structures 205 from the semiconductor device 105. The removal of the dummy gate structures 205 leaves behind openings (or recesses) in the dielectric layer 605, and provides access to the underlying sacrificial nanostructure layers 120. The dummy gate structures 205 may be removed in one or more etch operations. Such etch operations may include a plasma etch technique, a wet chemical etch technique, and/or another type of etch technique.

As further shown FIG. 7A, the replacement gate process includes a nanostructure release operation (e.g., an SiGe release operation). The nanostructure release operation is performed to remove the sacrificial nanostructure layers 120 (e.g., the silicon germanium layers). This results in openings 705 between the nanostructures channels 315 (e.g., the areas around the nanostructure channels 315). The sacrificial nanostructure layers 120 may be removed through the spaces that were previously occupied by the dummy gate structures 205. The nanostructure release operation may include the use of an etch tool to perform an etch operation to remove the sacrificial nanostructure layers 120 based on a difference in etch selectivity between the material of the sacrificial nanostructure layers 120 and the material of the nanostructure channels 315, and between the material of the sacrificial nanostructure layers 120 and the material of the inner spacers 410. The inner spacers 410 may function as etch stop layers in the etch operation to protect the source/drain regions 510 from being etched.

As shown in the cross-sectional plane B-B and the cross-sectional plane C-C in FIG. 7B, the replacement gate operation includes forming gate structures (e.g., replacement gate structures) 710 in the openings 705 between the source/drain regions 510 and between the inner spacers 410. In particular, the gate structures 710 fill the areas between and around the nanostructure channels 315 that were previously occupied by the sacrificial nanostructure layers 120 such that the gate structures 710 fully wrap around the nanostructure channels 315 and surround the nanostructure channels 315. This increases control of the nanostructure channel 315, increases drive current for the nanostructure transistor(s) of the semiconductor device 105, and/or reduces short channel effects (SCEs) for the nanostructure transistor(s) of the semiconductor device 105, among other examples. The gate structures 710 may also fill in the spaces that were previously occupied by the dummy gate structures 205. Portions of a gate structure 710 are formed in between pairs of nanostructure channels 315 in an alternating vertical arrangement. In other words, the semiconductor device 105 includes one or more vertical stacks of alternating nanostructure channels 315 and portions of a gate structure 710, as shown in FIG. 7B.

The gate structures 710 may each include a gate dielectric layer 715 and a metal gate electrode 720. A metal gate electrode 720 may include one or more metal materials such as tungsten (W), cobalt (Co), ruthenium (Ru), and/or titanium (Ti), among other examples. Additionally and/or alternatively, the gate structures 710 may each include one or more work function metal layers for tuning the work function of the metal gate electrode 720.

A gate dielectric layer 715 may be a conformal high-k dielectric liners that is deposited onto the nanostructure channels 315 and on sidewalls of the inner spacers 410 prior to formation of a gate electrode 720. The gate structures 710 may each include additional layers such as an interfacial layer, an adhesion layer, and/or a capping layer, among other examples. The gate dielectric layer 715 may include one or more high-k dielectric materials, such as a silicon nitride (SiₓN_{y}), a hafnium oxide (HfOₓ), a lanthanum oxide (LaOₓ), and/or another suitable high-k dielectric material.

Some source/drain regions 510 and gate structures 710 may be shared between two or more nanoscale transistors of the semiconductor device 105. In these implementations, one or more source/drain regions 510 and a gate structure 710 may be connected or coupled to a plurality of nanostructure channels 315, as shown in the example in FIG. 7B. This enables the plurality of nanostructure channels 315 to be controlled by a single gate structure 710 and a pair of source/drain regions 510.

As indicated above, FIGS. 7A and 7B are provided as an example. Other examples may differ from what is described with regard to FIGS. 7A and 7B.

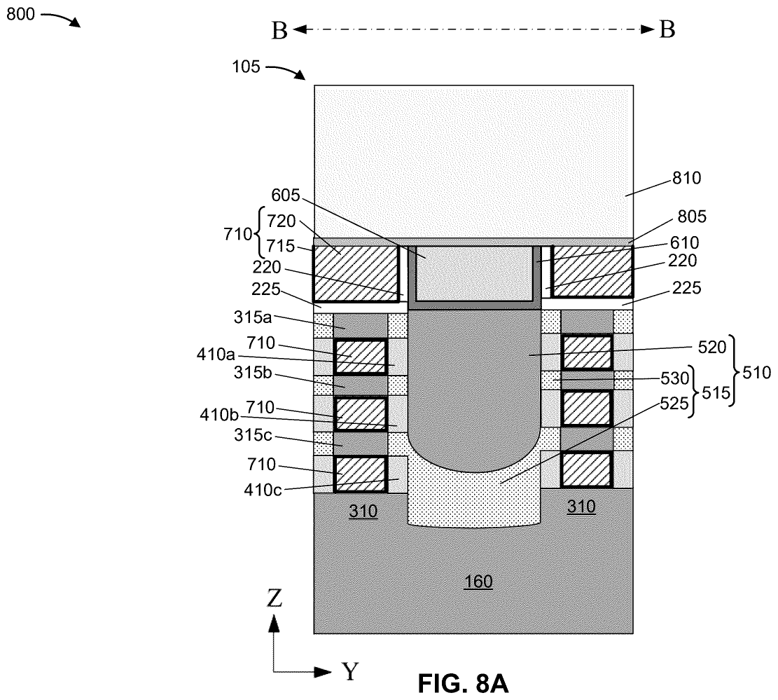

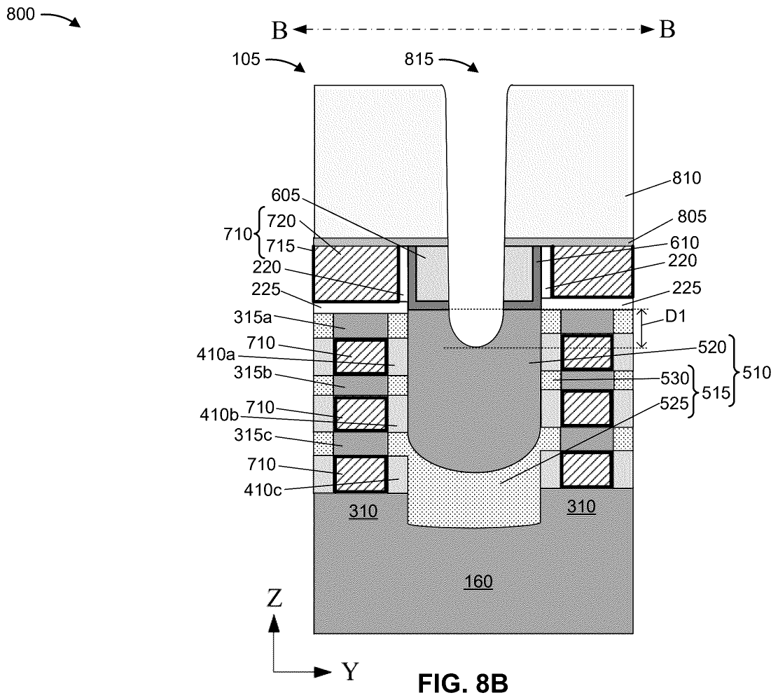

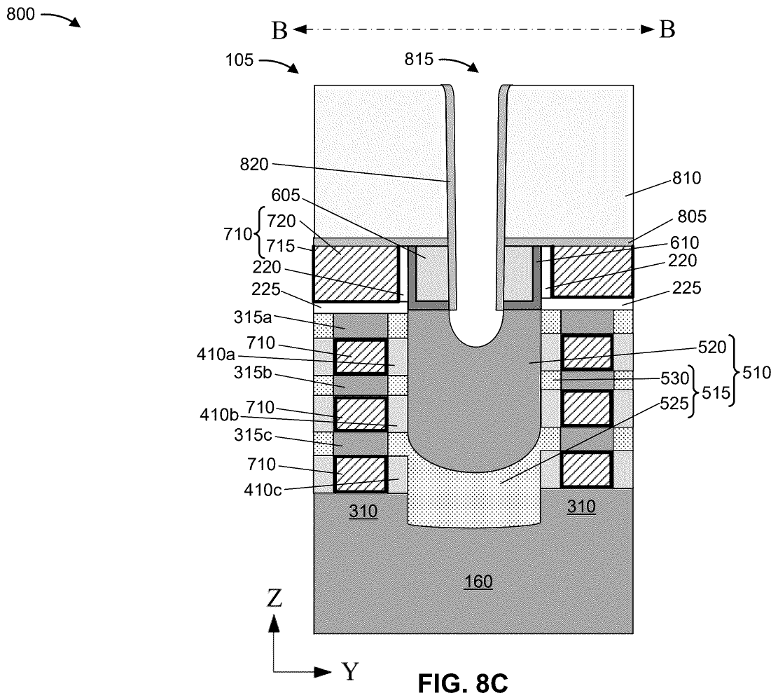

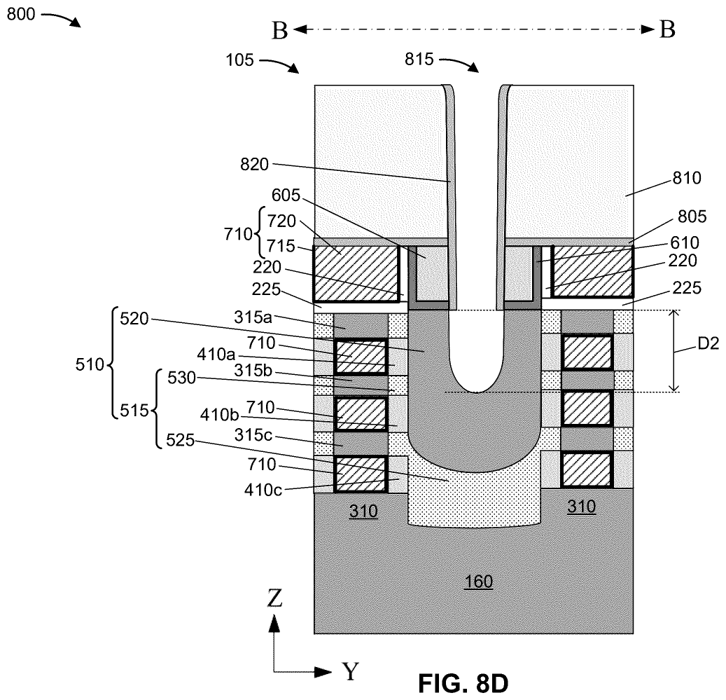

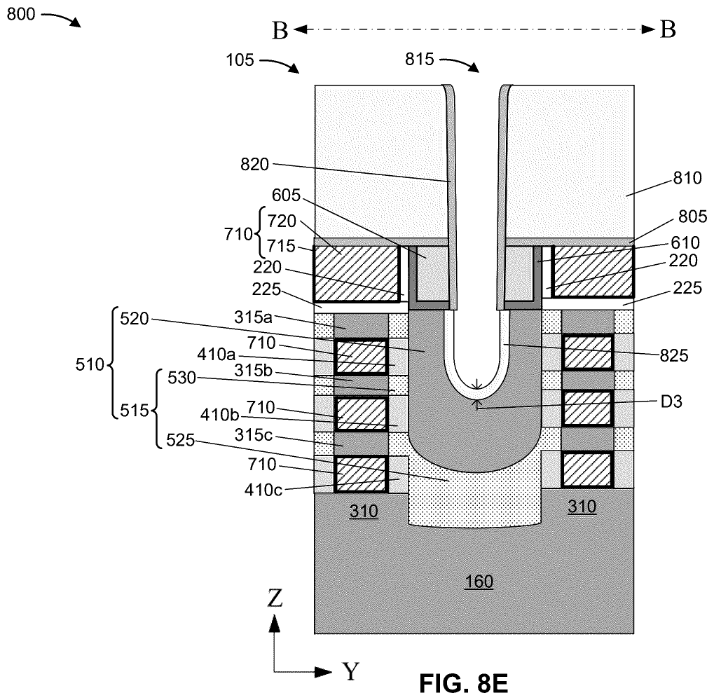

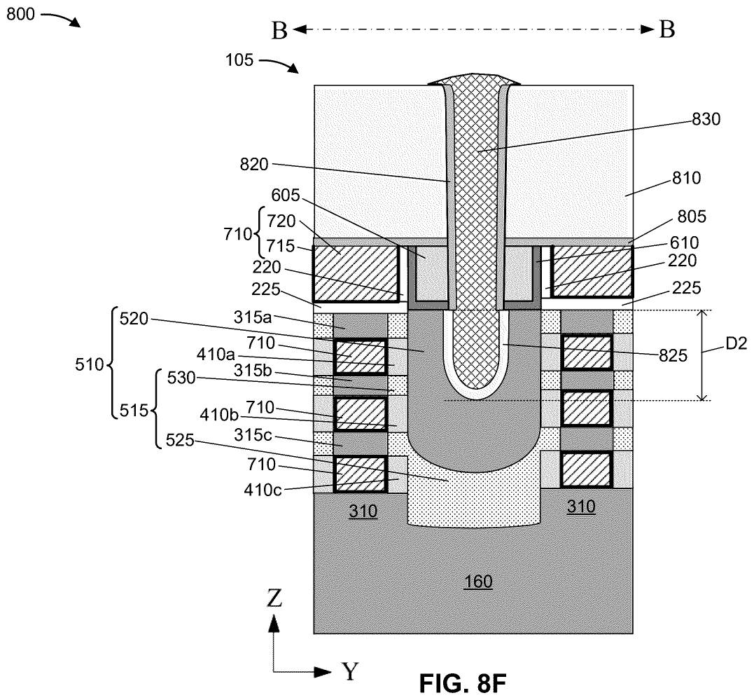

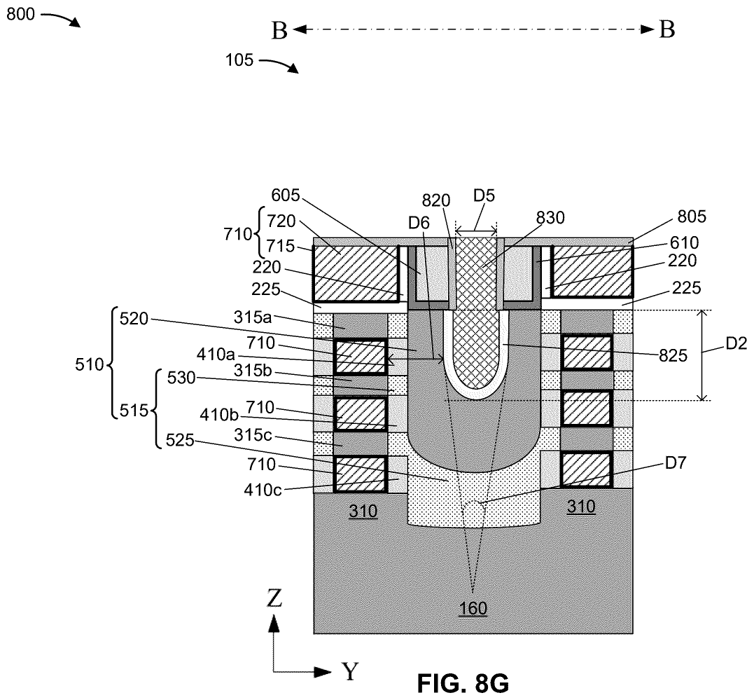

FIGS. 8A-8G are diagrams of an example implementation 800 of a source/drain contact formation process described herein. In particular, the example implementation 800 includes an example of forming a source/drain contact such that the source/drain contact is recessed within a source/drain region 510 of a nanostructure transistor of the semiconductor device 105 to achieve lower contact resistance and lower current crowding between the source/drain contact and the source/drain region 510. FIGS. 8A-8G are each illustrated from the perspective of the cross-sectional plane B-B in FIG. 2. In some implementations, the operations described in connection with the example implementation 800 are performed after the operations described in connection with FIGS. 1A-7B.

As shown in FIG. 8A, an etch stop layer (ESL) 805 may be formed above and/or on the dielectric layer 605, and above and/or on the top portions of the gate structures 710. Another dielectric layer 810 may be formed over and/or on the ESL 805.

The ESL 805 may include one or more dielectric materials, such as a silicon nitride (SiₓN_{y}), silicon carbon nitride (SiCN), carbon nitride (CN), silicon oxynitride (SiON), silicon carbon oxide (SiCO), or a combination thereof, among other examples. The dielectric layer 810 may be referred to as an ILD layer (e.g., an ILD1 layer), and may include one or more dielectric materials such as an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, the dielectric layer 810 includes an ELK dielectric material.

A deposition tool may be used to deposit the ESL 805 and/or the dielectric layer 810 using a PVD technique, an ALD technique, a CVD technique, and/or another suitable deposition technique. The ESL 805 and/or the dielectric layer 810 may be deposited in one or more deposition operations. In some implementations, a planarization tool may be used to perform a planarization operation (e.g., a CMP operation) to planarize the ESL 805 and/or the dielectric layer 810 after the ESL 805 and/or the dielectric layer 810 is deposited.

As shown in FIG. 8B, a contact recess 815 is formed through the dielectric layer 810, through the ESL 805, through the dielectric layer 605, through the CESL 610, and into the source/drain region 510. A first etch operation using an etch tool is performed to form the contact recess 815 to a first depth (indicated in FIG. 8B as dimension D1) relative to a top of the source/drain region 510. The contact recess 815 may extend into the second epitaxial layer 520 of the source/drain region 510. The bottom-most part of the contact recess 815, after the first etch operation, may be below the top nanostructure channels 315 (e.g., nanostructure channels 315a) and at least to the depth of the first layer of inner spacers 410 (e.g., inner spacers 410a). However, the contact recess 815 may be formed such that the bottom-most part of the contact recess 815 is located at a different depth in the semiconductor device 105 after the first etch operation.

In some implementations, a pattern in a photoresist layer is used to form the contact recess 815. In these implementations, a deposition tool may be used to form the photoresist layer on the dielectric layer 810 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the dielectric layer 810, the ESL 805, the dielectric layer 605, and/or the second epitaxial layer 520 of the source/drain region 510 based on the pattern to form the contact recess 815. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the contact recess 815 based on a pattern.

In some implementations, the first depth (the dimension D1) to which the contact recess 815 extends into the source/drain region 510 after the first etch operation may be included in a range of approximately 1 nanometer to approximately 9 nanometers. However, other values and ranges are within the scope of the present disclosure.

As shown in FIG. 8C, sidewall liners 820 may be formed on portions of the sidewalls of the contact recess 815 above the source/drain region 510. The sidewall liners 820 may be formed as protective liners that protect the sidewalls of the contact recess 815 from being etched (and therefore, the lateral width of the contact recess 815 widened) during a second etch operation that is to be subsequently performed to increase the depth of the contact recess 815. Additionally and/or alternatively, the sidewall liners 820 may include barrier liners that are included to reduce and/or prevent diffusion of material from a source/drain contact (e.g., that is to be formed in the contact recess 815) into the surrounding dielectric layers.

The sidewall liners 820 may include one or more dielectric materials. For example, the sidewall liners 820 may include a silicon nitride (SiₓN_{y} such as Si₃N₄), a silicon oxynitride (SiON), a silicon oxycarbide (SiOC), a silicon oxycarbonitride (SiOCN), and/or another suitable dielectric material. The material of the sidewall liners 820 may be different than the material of the source/drain region 510 (e.g., than the semiconductor material of the second epitaxial layer 520) to provide etch selectivity between the sidewall liners 820 and the source/drain region 510. This enables the source/drain region 510 to be further etched in the second etch operation to increase the depth of the contact recess 815 with minimal to no consumption of the sidewall liners 820.

To form the sidewall liners 820, a conformal layer of dielectric material may be deposited on the sidewalls of the contact recess 815 (e.g., corresponding to exposed surfaces of the dielectric layer 605, exposed surfaces of the ESL 805, and exposed surfaces of the dielectric layer 810) and on the bottom surface of the contact recess 815 (e.g., corresponding to the exposed surfaces of the second epitaxial layer 520 of the source/drain region 510). A deposition tool may be used to deposit the conformal layer of dielectric material using a deposition technique such as ALD and/or CVD, among other examples.

An etch tool may be used to trim the portion of the conformal layer of dielectric material located on the bottom surface of the contact recess 815 so that the conformal layer of dielectric material is removed from the surface of the second epitaxial layer 520 of the source/drain region 510. In this way, the surface of the second epitaxial layer 520 of the source/drain region 510 is exposed again through the contact recess 815, and the remaining portions of the conformal layer of dielectric material located on the sidewalls of the contact recess 815 correspond to the sidewall liners 820.

An anisotropic etch technique may be used to trim the portion of the conformal layer of dielectric material located on the bottom surface of the contact recess 815 so that the portions of the conformal layer of dielectric material located on the sidewalls of the contact recess 815 remain as the sidewall liners 820. For example, a plasma-based etch technique (such as a reactive ion etch (RIE) technique) may be used to perform a primarily vertical (e.g., z-direction) etch to trim the conformal layer of dielectric material. However, other etch techniques are within the scope of the present disclosure.

As shown in FIG. 8D, a second etch operation is performed (e.g., after the first etch operation described in connection with FIG. 8B) to increase the depth of the contact recess 815 in the source/drain region 510 from the first depth (dimension D1) to a second depth (indicated in FIG. 8D as a dimension D2). In this way, the contact recess 815 extends further/deeper into the second epitaxial layer 520 of the source/drain region 510 after the second etch operation than after the first etch operation. For example, after the first etch operation described in connection with FIG. 8B, the contact recess 815 may extend to a depth of a top-most nanostructure channel (e.g., a nanostructure channel 315a). The bottom-most part of the contact recess 815, after the second etch operation, may be below middle nanostructure channels 315 (e.g., nanostructure channels 315c) and at least to the depth of the second layer of inner spacers 410 (e.g., inner spacers 410b). However, the contact recess 815 may be formed such that the bottom-most part of the contact recess 815 is located at a different depth in the semiconductor device 105 after the second etch operation.

In some implementations, the second depth is included in a range of approximately 10 nanometers to approximately 60 nanometers. However, other values and ranges are within the scope of the present disclosure. In some implementations, a ratio of the second depth to the first depth is included in a range of approximately 1.1:1 to approximately 60:1. However, other values and ranges are within the scope of the present disclosure.

The second etch operation may be different from the first etch operation in that the first etch operation is performed using a first etchant, and the second etch operation is performed using a second etchant that is different than the first etchant. For example, the first etch operation may be performed using a plasma-based etchant and the second etch operation may be performed using a gas-based etchant.

Different etchants may be used for the first etch operation and the second etch operation to achieve different etch selectivity for the first etch operation and the second etch operation. For example, the first etchant used in the first etch operation may be selected to achieve a low etch selectivity between the dielectric layers above the source/drain region 510 (e.g., the dielectric layer 605, the ESL 805, the dielectric layer 810) and the semiconductor material of the source/drain region 510 (e.g., the semiconductor material of the second epitaxial layer 520). This enables the contact recess 815 to be formed through the dielectric layer 605, the ESL 805, the dielectric layer 810, and into the source/drain region 510 in the first etch operation.

For the second etch operation, the second etchant may be selected to achieve a high etch selectivity between the dielectric layers above the source/drain region 510 (e.g., the dielectric layer 605, the ESL 805, the dielectric layer 810, the sidewall liners 820) and the semiconductor material of the source/drain region 510 (e.g., the semiconductor material of the second epitaxial layer 520). In particular, a gas-based etchant such as a chlorine-containing gas and/or another suitable gas-based etchant may be used in the second etch operation so that the etch rate of the second etchant for the semiconductor material of the source/drain region 510 is greater than the etch rate of the second etchant for the dielectric material of the sidewalls (e.g., the silicon nitride material of the sidewall liners 820) of the contact recess 815. This enables the depth of the contact recess 815 to be increased in the source/drain region 510 with minimal to no etching of the dielectric material of the sidewalls of the contact recess 815 (and thus, minimal to no increase in the lateral width of the contact recess 815).

As shown in FIG. 8E, a metal silicide layer 825 is formed at the bottom of the contact recess 815. In particular, the metal silicide layer 825 may be formed from the surface of the source/drain region 510 (e.g., the surface of the second epitaxial layer 520 of the source/drain region 510) exposed in the contact recess 815. To form the metal silicide layer 825, a salicidation process may be performed. The salicidation process includes using a deposition tool to deposit (e.g., by CVD, ALD, PVD, and/or electroplating) a layer of metal material on the surface of the second epitaxial layer 520 of the source/drain region 510 exposed in the contact recess 815. An annealing operation may be performed to increase the temperature of the layer of metal material and the surface of the second epitaxial layer 520 of the source/drain region 510 exposed in the contact recess 815 to cause the metal material to diffuse into the surface of the second epitaxial layer 520 of the source/drain region 510 exposed in the contact recess 815. This results in formation of the metal silicide layer 825. In other words, the surface of the second epitaxial layer 520 of the source/drain region 510 exposed in the contact recess 815 may be transformed from a semiconductor surface to a metal silicide surface.

In some implementations, the layer of metal material includes titanium (Ti) and the metal silicide layer 825 includes titanium silicide (TiSi). In some implementations, the layer of metal material includes ruthenium (Ru) and the metal silicide layer 825 includes ruthenium silicide (RuSi). In some implementations, the layer of metal material includes cobalt (Co) and the metal silicide layer 825 includes cobalt silicide (CoSi).

The metal silicide layer 825 is formed to a thickness (indicated in FIG. 8E as a dimension D3) that is included in a range of approximately 3.5 nanometers to approximately 7 nanometers. However, other values and ranges are within the scope of the present disclosure.

As shown in FIG. 8F, the remaining area in the contact recess 815 may be filled in with material of a source/drain contact 830 such that the source/drain contact 830 extends through the dielectric layer 810, through the ESL 805, and through the dielectric layer 605. Moreover, a bottom of the source/drain contact 830 is recessed within the source/drain region 510. In this way, the source/drain contact 830 and the metal silicide layer 825 extend into the source/drain region 510 to a depth corresponding to the dimension D2. The sidewall liners 820 may be located between the source/drain contact 830 and the dielectric layer 605, between the source/drain contact 830 and the ESL 805, and/or between the source/drain contact 830 and the dielectric layer 810.

The source/drain contact 830 may include a contact plug, a via, a conductive column, a conductive pillar, and/or another type of conductive structure that is elongated in the z-direction in the semiconductor device 105. The source/drain contact 830 may include one or more electrically conductive materials such as tungsten (W), ruthenium (Ru), cobalt (Co), titanium (Ti), molybdenum (Mo), copper (Cu), and/or aluminum (Al), among other examples.

A deposition tool may be used to deposit the material of the source/drain contact 830 in the contact recess 815 using a CVD technique, an ALD technique, a PVD technique, an electroplating technique, and/or another suitable deposition technique. In some implementations, a seed layer is deposited in the contact recess 815, and the material of the source/drain contact 830 is deposited on the seed layer.

In some implementations, the source/drain contact 830 includes a multiple-layer structure. For example, the source/drain contact 830 may include one or more liners that are deposited on the sidewalls and bottom surface of the contact recess 815, and a bulk fill layer that is formed on the one or more liners. The one or more liners may include different materials. For example, a first liner may include a silicon nitride (SiₓN_{y}) liner, and a second liner may include a silicon oxide (SiOₓ) liner. As another example, a first liner may include a titanium nitride (TiN) liner, and a second liner may include a silicon oxynitride (SiON) liner. The bulk layer may include the electrically conductive material of the source/drain contact 830.

The increased depth to which the source/drain contact 830 is recessed within the source/drain region 510 in the semiconductor device 105 may reduce the contact resistance between the source/drain contact 830 and the source/drain region 510 because of the increased contact area between the source/drain contact 830 and the source/drain region 510. The increased contact area is achieved in that the source/drain contact 830 being recessed within the source/drain region 510 results in portions of the sidewalls of the source/drain contact 830 being in contact with the source/drain region 510, in addition to the bottom surface of the source/drain contact 830 being in contact with the source/drain region 510.

Additionally and/or alternatively, the increased depth to which the source/drain contact 830 is recessed within the source/drain region 510 in the semiconductor device 105 may reduce current crowding in the source/drain region 510 because the source/drain contact 830 extends alongside the top-most nanostructure channels (e.g., the nanostructure channels 315a), and in some implementations, alongside the middle nanostructure channels (e.g., the nanostructure channels 315b). This provides for a more direct lateral path of travel for charge carriers between the source/drain contact 830 and the nanostructure channels 315 through the source/drain region 510 (e.g., as opposed to the charge carriers having to travel vertically in addition to horizontally to reach the nanostructure channels 315a and 315b if the source/drain contact 830 terminated at the top of the source/drain recess 510).

As shown in FIG. 8G, a planarization tool may be used to perform a planarization operation (e.g., a CMP operation) to planarize the semiconductor device 105. In the planarization operation, excess material of the source/drain contact 830 is removed, and the dielectric layer 810 may be removed. The planarization operation may be stopped once the ESL 805 is reached.

In this way, the semiconductor device 105 may include a plurality of nanostructure channels 315 arranged in a first direction (e.g., the nanostructure channels 315a-315c arranged in the z-direction) in the semiconductor device 105. The semiconductor device 105 may include a gate structure 710 wrapping around the plurality of nanostructure channels 315. The semiconductor device 105 may include a source/drain region 510 adjacent to (e.g., laterally adjacent to) a side of the gate structure 710 and laterally adjacent to ends of the plurality of nanostructure channels 315 in a second direction (e.g., in the y-direction) that is approximately perpendicular to the first direction. The semiconductor device 105 may include a plurality of inner spacers 410 (e.g., inner spacers 410a-410c arranged in the z-direction) between the source/drain region 510 and the gate structure 710. The semiconductor device 105 may include a source/drain contact 830 extending (e.g., in the z-direction) into the source/drain region 510 to a depth (e.g., the dimension D2) that is lower than top-most inner spacers (e.g., the inner spacers 410a) and that is lower than the top-most nanostructure channels (e.g., the nanostructure channels 315a). A second epitaxial layer 520 of the source/drain region 510 may surround sidewalls of the source/drain contact 830, and a first epitaxial layer 515 of the source/drain region 515 located between the second epitaxial region 520 and the nanostructure channels 315.

The source/drain contact 830 may extend into the source/drain region 510 to a depth of middle nanostructure channels (e.g., nanostructure channels 315b). For example, source/drain contact 830 may extend into the source/drain region 510 lower than a depth of the top surfaces of the middle nanostructure channels. As another example, the source/drain contact 830 may extend into the source/drain region 510 lower than or approximately equal to a depth of the bottom surfaces of the middle nanostructure channels. The semiconductor device 105 may include a metal silicide layer 825 between the source/drain contact 830 and the source/drain region 510, and the metal silicide layer 825 may extend from a top of the source/drain region 510 to a bottom of the source/drain contact 830.

The source/drain contact 830 may electrically connect the source/drain region 510 to an interconnect layer (e.g., a back end region or a back end of line (BEOL) region) of the semiconductor device 105. This enables electrical signals and/or electrical power to be routed between one or more conductive structures (not shown) in the interconnect layer and the source/drain region 510 through the source/drain contact 830.

As further shown in FIG. 8G, a lateral width of the source/drain contact 830 (indicated in FIG. 8G as a dimension D5) is included in a range of approximately 10 nanometers to approximately 30 nanometers. However, other values and ranges are within the scope of the present disclosure. A lateral distance between the metal silicide layer 825 and the gate structure 710 laterally adjacent to the source/drain contact 830 (indicated in FIG. 8G as a dimension D6) is included in a range of approximately 2 nanometers to approximately 20 nanometers. However, other values and ranges are within the scope of the present disclosure. An angle between the segments of the metal silicide layer 825 on the sidewalls the source/drain contact 830 (indicated in FIG. 8G as a dimension D7) is included in a range of approximately 10 degrees to approximately 115 degrees. However, other values and ranges are within the scope of the present disclosure. In some implementations, a ratio of the depth to which the source/drain contact 830 is recessed within the source/drain region 510 (dimension D2) to the lateral width of the source/drain contact 830 (dimension D3) is included in a range of approximately 1:3 to approximately 6:1. However, other values and ranges are within the scope of the present disclosure.

As indicated above, FIGS. 8A-8G are provided as an example. Other examples may differ from what is described with regard to FIGS. 8A-8G.

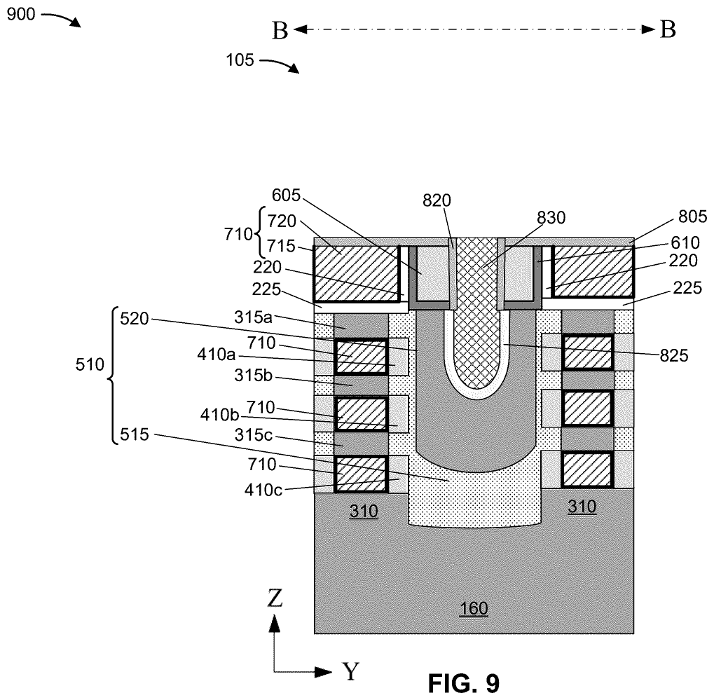

FIG. 9 is a diagram of an example implementation 900 of the semiconductor device 105 described herein. The example implementation 900 of the semiconductor device 105 may be formed by similar processes described in connection with FIGS. 1A-8G, except that the first epitaxial layer 515 of a source/drain region 510 of the semiconductor device 105 is formed to include a merged epitaxial region 905 as opposed to a merged region 525 and a non-contiguous second epitaxial regions 530.

To achieve the merged epitaxial region 905, the material of the first epitaxial layer 515 is epitaxially grown during the source/drain region formation process described in connection with FIG. 5 such that the merged region 525 and the non-contiguous second epitaxial regions 530 are merged together to form a plurality of contiguous regions of epitaxial material corresponding to the merged epitaxial region 905. The epitaxial material corresponding to the merged epitaxial region 905 spans across the inner spacers 405 such that the second epitaxial layer 520 of the source/drain region 510 is spaced apart from (and not in contact with) the inner spacers 405.

As indicated above, FIG. 9 is provided as an example. Other examples may differ from what is described with regard to FIG. 9.

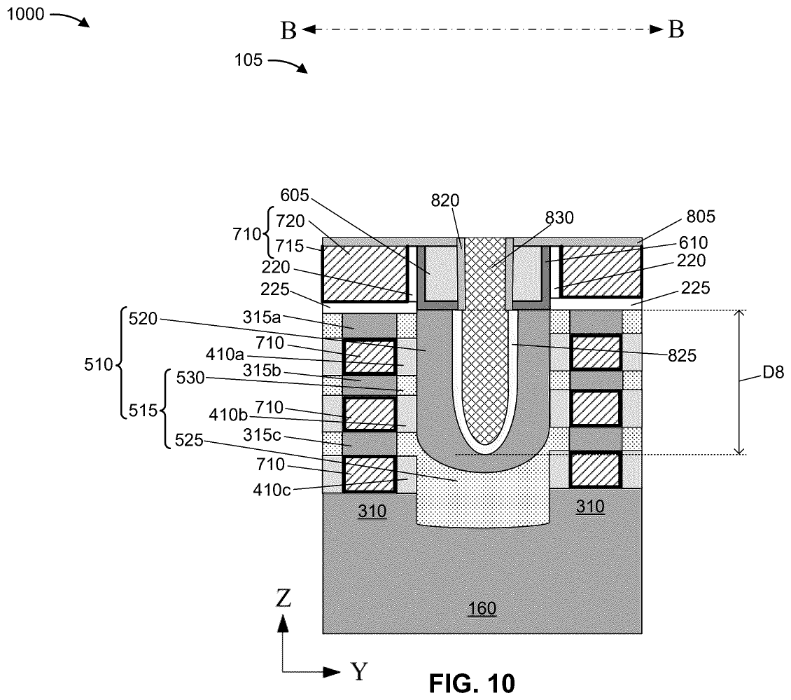

FIG. 10 is a diagram of an example implementation 1000 of the semiconductor device 105 described herein. The example implementation 1000 of the semiconductor device 105 may be formed by similar processes described in connection with FIGS. 1A-8G, except that a source/drain contact 830 in the example implementation 1000 of the semiconductor device 105 is recessed deeper in a source/drain region 510 than illustrated in FIGS. 8A-8G. For example, the source/drain contact 830 in the example implementation 1000 extends to a depth (e.g., relative to a top of the source/drain region 510) corresponding to a dimension D8, and the dimension D8 is greater than the dimension D2 in FIG. 8D.

To achieve this, the etch operation described in connection with FIG. 8D is performed to increase the depth of the contact recess 815 from the dimension D1 to the dimension D8. Thus, after the etch operation described in connection with FIG. 8D, the bottom of the contact recess 815 is at a depth (e.g., the dimension D8) in the semiconductor device 105 that is approximately equal to or lower than a bottom-most nanostructure channel (e.g., a nanostructure channel 315c) of the semiconductor device 105. In some implementations, the bottom of the contact recess 815 is at a depth (e.g., the dimension D8) in the semiconductor device 105 that is approximately equal to or lower than a bottom surface of the bottom-most nanostructure channel (e.g., the nanostructure channel 315c) after the etch operation described in connection with FIG. 8D.

The metal silicide layer 825 is then formed from the exposed portions of the second epitaxial layer 520 in the contact recess 815, and the material of the source/drain contact 830 is deposited on the metal silicide layer 825 such that the source/drain contact 830 fills in the remaining area in the contact recess 815 and extends above the source/drain region 510.

Thus, the metal silicide layer 825 and/or the source/drain contact 830 may be located at a depth in the semiconductor device 105 that is approximately equal to or lower than a bottom-most nanostructure channel (e.g., a nanostructure channel 315c) of the semiconductor device 105, and that is lower than top and middle inner spacers (e.g., inner spacers 405a and 410b). In some implementations, the metal silicide layer 825 and/or the source/drain contact 830 may be located at a depth in the semiconductor device 105 that is approximately equal to or lower than a bottom surface of the bottom-most nanostructure channel (e.g., the nanostructure channel 315c), and/or that is approximately equal or lower than a top surface of the bottom-most inner spacers (e.g., inner spacers 405c).

The increased depth to which the source/drain contact 830 is recessed within the source/drain region 510 in the example implementation 1000 of the semiconductor device 105 may further reduce the contact resistance between the source/drain contact 830 and the source/drain region 510 because the further increased contact area between the source/drain contact 830 and the source/drain region 510. Additionally and/or alternatively, the increased depth to which the source/drain contact 830 is recessed within the source/drain region 510 in the example implementation 1000 of the semiconductor device 105 may further reduce current crowding in the source/drain region 510 because the source/drain contact 830 extends alongside the middle nanostructure channels (e.g., the nanostructure channels 315b) and alongside the bottom-most nanostructure channels (e.g., the nanostructure channels 315c). This provides for a more direct lateral path of travel for charge carriers between the source/drain contact 830 and the nanostructure channels 315 through the source/drain region 510 (e.g., as opposed to the charge carriers having to travel vertically in addition to horizontally to reach the nanostructure channels 315b and 315c if the source/drain contact 830 terminated at the top of the source/drain recess 510).

As indicated above, FIG. 10 is provided as an example. Other examples may differ from what is described with regard to FIG. 10.

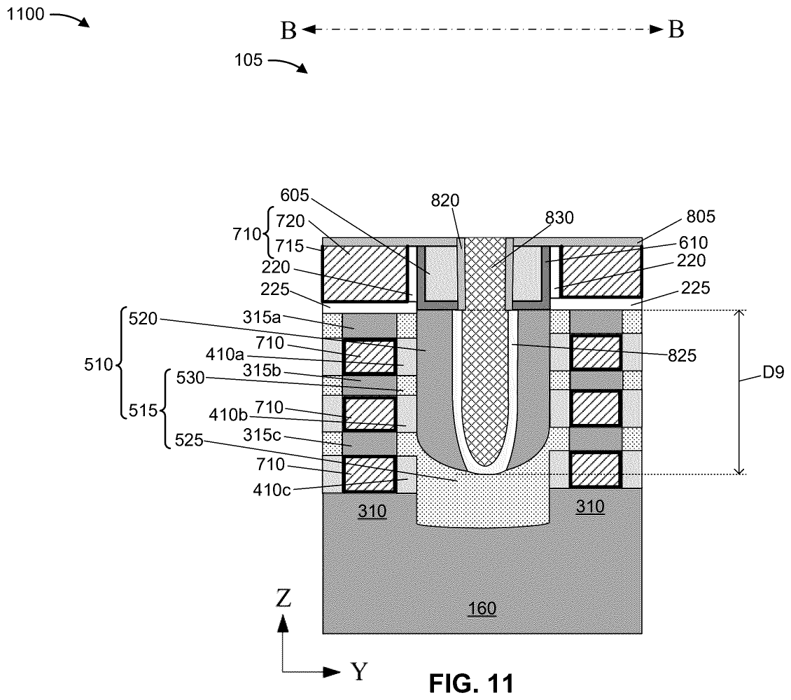

FIG. 11 is a diagram of an example implementation 1100 of the semiconductor device 105 described herein. The example implementation 1100 of the semiconductor device 105 may be formed by similar processes described in connection with FIGS. 1A-8G, except that a source/drain contact 830 in the example implementation 1100 of the semiconductor device 105 is recessed deeper in a source/drain region 510 than illustrated in FIGS. 8A-8G. For example, the source/drain contact 830 in the example implementation 1100 extends to a depth (e.g., relative to a top of the source/drain region 510) corresponding to a dimension D9, and the dimension D9 is greater than the dimension D2 in FIG. 8D.

To achieve this, the etch operation described in connection with FIG. 8D is performed to increase the depth of the contact recess 815 from the dimension D1 to the dimension D9. Thus, after the etch operation described in connection with FIG. 8D, the bottom of the contact recess 815 is at a depth (e.g., the dimension D9) in the semiconductor device 105 that is below a bottom-most nanostructure channel (e.g., a nanostructure channel 315c) of the semiconductor device 105. The recess 815 may extend to a depth of the mesa region 310 under the nanostructure channels 315. The recess 815 may extend through the second epitaxial layer 520 and into a portion of the merged region 525 of the first epitaxial layer 515 under the second epitaxial layer 520.

The metal silicide layer 825 is then formed from the exposed portions of the second epitaxial layer 520 in the contact recess 815 and from an exposed portion of the merged region 525 of the first epitaxial layer 515 in the contact recess 815. Thus, the bottom of the metal silicide layer 825 may be in contact with the merged region 525 of the first epitaxial layer 515, and the portions of the metal silicide layer 825 extending along the sidewalls of the contact recess 815 may be in contact with the second epitaxial layer 520. The material of the source/drain contact 830 is deposited on the metal silicide layer 825 such that the source/drain contact 830 fills in the remaining area in the contact recess 815 and extends above the source/drain region 510.

Thus, the metal silicide layer 825 and/or the source/drain contact 830 may be located at a depth in the semiconductor device 105 that is lower than bottom-most nanostructure channels (e.g., nanostructure channels 315c) of the semiconductor device 105, and that is lower than bottom-most inner spacers (e.g., inner spacers 405c). In some implementations, the metal silicide layer 825 and/or the source/drain contact 830 may be located at a depth in the semiconductor device 105 that is approximately equal to a mesa region 310 under the nanostructure channels 315.

The increased depth to which the source/drain contact 830 is recessed within the source/drain region 510 in the example implementation 1100 of the semiconductor device 105 may further reduce the contact resistance between the source/drain contact 830 and the source/drain region 510 because of the further increased contact area between the source/drain contact 830 and the source/drain region 510. Additionally and/or alternatively, the increased depth to which the source/drain contact 830 is recessed within the source/drain region 510 in the example implementation 1100 of the semiconductor device 105 may further reduce current crowding in the source/drain region 510 because the source/drain contact 830 extends alongside the middle nanostructure channels (e.g., the nanostructure channels 315b) and alongside the bottom-most nanostructure channels (e.g., the nanostructure channels 315c). This provides for a more direct lateral path of travel for charge carriers between the source/drain contact 830 and the nanostructure channels 315 through the source/drain region 510 (e.g., as opposed to the charge carriers having to travel vertically in addition to horizontally to reach the nanostructure channels 315b and 315c if the source/drain contact 830 terminated at the top of the source/drain recess 510).

As indicated above, FIG. 11 is provided as an example. Other examples may differ from what is described with regard to FIG. 11.

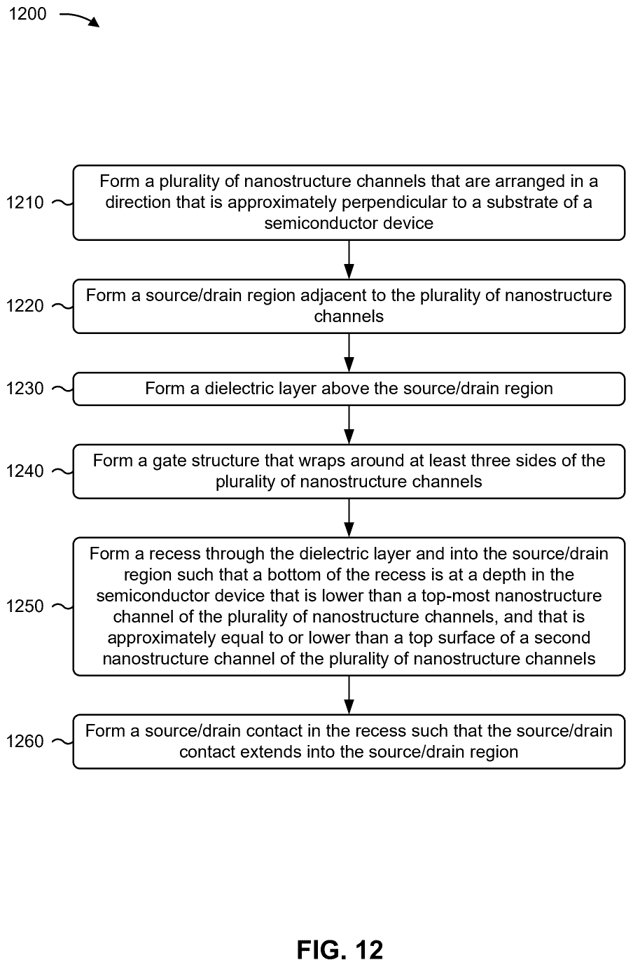

FIG. 12 is a flowchart of an example process 1200 associated with forming a semiconductor device described herein. In some implementations, one or more process blocks of FIG. 12 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 12, process 1200 may include forming a plurality of nanostructure channels that are arranged in a direction that is approximately perpendicular to a substrate of a semiconductor device (block 1210). For example, one or more semiconductor processing tools may be used to form a plurality of nanostructure channels (e.g., nanostructure channels 315) that are arranged in a direction (e.g., a z-direction) that is approximately perpendicular to a substrate (e.g., a semiconductor substrate 110) of a semiconductor device (e.g., a semiconductor device 105), as described herein.

As further shown in FIG. 12, process 1200 may include forming a source/drain region adjacent to the plurality of nanostructure channels (block 1220). For example, one or more semiconductor processing tools may be used to form a source/drain region (e.g., a source/drain region 510) adjacent to the plurality of nanostructure channels, as described herein.

As further shown in FIG. 12, process 1200 may include forming a dielectric layer above the source/drain region (block 1230). For example, one or more semiconductor processing tools may be used to form a dielectric layer (e.g., a dielectric layer 605) above the source/drain region, as described herein.

As further shown in FIG. 12, process 1200 may include forming a gate structure that wraps around at least three sides of the plurality of nanostructure channels (block 1240). For example, one or more semiconductor processing tools may be used to form a gate structure (e.g., a gate structure 710) that wraps around at least three sides of the plurality of nanostructure channels, as described herein.

As further shown in FIG. 12, process 1200 may include forming a recess through the dielectric layer and into the source/drain region such that a bottom of the recess is at a depth in the semiconductor device that is lower than a top-most nanostructure channel of the plurality of nanostructure channels, and that is approximately equal to or lower than a top surface of a second nanostructure channel of the plurality of nanostructure channels (block 1250). For example, one or more semiconductor processing tools may be used to form a recess (e.g., a contact recess 815) through the dielectric layer and into the source/drain region such that a bottom of the recess is at a depth (e.g., a dimension D2, a dimension D8, a dimension D9) in the semiconductor device that is lower than a top-most nanostructure channel (e.g., a nanostructure channel 315a) of the plurality of nanostructure channels, and that is approximately equal to or lower than a top surface of a second nanostructure channel (e.g., a nanostructure channel 315b) of the plurality of nanostructure channels, as described herein. In some implementations, the second nanostructure channel is below the top-most nanostructure channel.

As further shown in FIG. 12, process 1200 may include forming a source/drain contact in the recess such that the source/drain contact extends into the source/drain region (block 1260). For example, one or more semiconductor processing tools may be used to form a source/drain contact (e.g., a source/drain contact 830) in the recess such that the source/drain contact extends into the source/drain region, as described herein.

Process 1200 may include additional implementations, such as any single implementation or any combination of implementations described below and/or in connection with one or more other processes described elsewhere herein.

In a first implementation, forming the recess includes forming the recess such that the bottom of the recess is at a depth (e.g., the dimension D2) in the semiconductor device that is approximately equal to or lower than a bottom surface of the second nanostructure channel.

In a second implementation, alone or in combination with the first implementation, forming the recess includes forming the recess such that the bottom of the recess is at a depth (e.g., the dimension D8) in the semiconductor device that is approximately equal to or lower than a bottom surface of a bottom-most nanostructure channel (e.g., a nanostructure channel 315c) of the plurality of nanostructure channels.

In a third implementation, alone or in combination with one or more of the first and second implementations, forming the source/drain contact includes forming a metal silicide layer (e.g., a metal silicide layer 825) in the recess, and forming the source/drain contact on the metal silicide layer.

In a fourth implementation, alone or in combination with one or more of the first through third implementations, forming the source/drain region includes forming a first layer of epitaxially-grown material (e.g., a first epitaxial layer 515) that is in contact with the plurality of nanostructure channels, and forming a second layer of epitaxially-grown material (e.g., a second epitaxial layer 520) on the first layer of epitaxially-grown material, and forming the metal silicide layer includes forming the metal silicide layer such that the metal silicide layer is in contact with the second layer of epitaxially-grown material and is spaced apart from the first layer of epitaxially-grown material by the second layer of epitaxially-grown material.

In a fifth implementation, alone or in combination with one or more of the first through fourth implementations, the first layer of epitaxially-grown material includes a plurality of non-contiguous portions (e.g., non-contiguous second epitaxial regions 530) that are in contact with the plurality of nanostructure channels.

In a sixth implementation, alone or in combination with one or more of the first through fifth implementations, the first layer of epitaxially-grown material includes a plurality of contiguous portions (e.g., a merged epitaxial region 905) that are in contact with the plurality of nanostructure channels.

In a seventh implementation, alone or in combination with one or more of the first through sixth implementations, forming the source/drain region includes forming a first layer of epitaxially-grown material (e.g., a first epitaxial layer 515) that is in contact with the plurality of nanostructure channels, and forming a second layer of epitaxially-grown material (e.g., a second epitaxial layer 520) on the first layer of epitaxially-grown material, and forming the recess includes forming the recess such that the bottom of the recess extends through the second layer of epitaxially-grown material and into the first layer of epitaxially-grown material, and forming the metal silicide layer includes forming the metal silicide layer such that first portions of the metal silicide layer are in contact with the second layer of epitaxially-grown material, and such that a second portion of the metal silicide layer is in contact with first layer of epitaxially-grown material.

Although FIG. 12 shows example blocks of process 1200, in some implementations, process 1200 includes additional blocks, fewer blocks, different blocks, or differently arranged blocks than those depicted in FIG. 12. Additionally, or alternatively, two or more of the blocks of process 1200 may be performed in parallel.

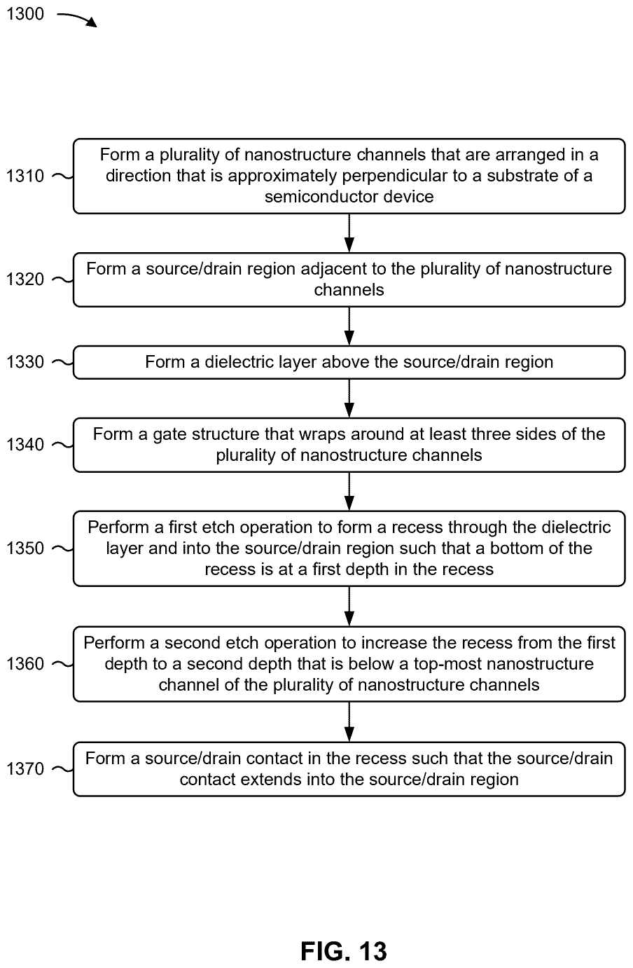

FIG. 13 is a flowchart of an example process 1300 associated with forming a semiconductor device described herein. In some implementations, one or more process blocks of FIG. 13 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 13, process 1300 may include forming a plurality of nanostructure channels that are arranged in a direction that is approximately perpendicular to a substrate of a semiconductor device (block 1310). For example, one or more semiconductor processing tools may be used to form a plurality of nanostructure channels (e.g., nanostructure channels 315) that are arranged in a direction (e.g., a z-direction) that is approximately perpendicular to a substrate (e.g., a semiconductor substrate 110) of a semiconductor device (e.g., a semiconductor device 105), as described herein.

As further shown in FIG. 13, process 1300 may include forming a source/drain region adjacent to the plurality of nanostructure channels (block 1320). For example, one or more semiconductor processing tools may be used to form a source/drain region (e.g., a source/drain region 510) adjacent to the plurality of nanostructure channels, as described herein.

As further shown in FIG. 13, process 1300 may include forming a dielectric layer above the source/drain region (block 1330). For example, one or more semiconductor processing tools may be used to form a dielectric layer (e.g., a dielectric layer 605) above the source/drain region, as described herein.

As further shown in FIG. 13, process 1300 may include forming a gate structure that wraps around at least three sides of the plurality of nanostructure channels (block 1340). For example, one or more semiconductor processing tools may be used to form a gate structure (e.g., a gate structure 710) that wraps around at least three sides of the plurality of nanostructure channels, as described herein.

As further shown in FIG. 13, process 1300 may include performing a first etch operation to form a recess through the dielectric layer and into the source/drain region such that a bottom of the recess is at a first depth in the recess (block 1350). For example, one or more semiconductor processing tools may be used to perform a first etch operation to form a recess (e.g., a contact recess 815) through the dielectric layer and into the source/drain region such that a bottom of the recess is at a first depth (e.g., a dimension D1) in the recess, as described herein.

As further shown in FIG. 13, process 1300 may include performing a second etch operation to increase the recess from the first depth to a second depth that is below a top-most nanostructure channel of the plurality of nanostructure channels (block 1360). For example, one or more semiconductor processing tools may be used to perform a second etch operation to increase the recess from the first depth to a second depth (e.g., a dimension D2, a dimension D8, a dimension D9) that is below a top-most nanostructure channel of the plurality of nanostructure channels, as described herein.

As further shown in FIG. 13, process 1300 may include forming a source/drain contact in the recess such that the source/drain contact extends into the source/drain region (block 1370). For example, one or more semiconductor processing tools may be used to form a source/drain contact (e.g., a source/drain contact 830) in the recess such that the source/drain contact extends into the source/drain region, as described herein.

Process 1300 may include additional implementations, such as any single implementation or any combination of implementations described below and/or in connection with one or more other processes described elsewhere herein.

In a first implementation, process 1300 includes forming, after the first etch operation and prior to the second etch operation, a protective liner (e.g., a sidewall liner 820) on sidewalls of the recess and on a top of the source/drain region in the recess, and performing, after the first etch operation and prior to the second etch operation, a third etch operation to etch through the protective liner to expose the top of the source/drain region through the recess.

In a second implementation, alone or in combination with the first implementation, performing the second etch operation includes performing the second etch operation while the protective liner is on the sidewalls of the recess.

In a third implementation, alone or in combination with one or more of the first and second implementations, performing the first etch operation includes performing the first etch operation using a first etchant, and performing the second etch operation includes performing the second etch operation using a second etchant, where the first etchant and the second etchant are different etchants.

In a fourth implementation, alone or in combination with one or more of the first through third implementations, a first etch rate of the second etchant for a material of sidewalls of the recess is less than a second etch rate of the second etchant for a material of the source/drain region.

In a fifth implementation, alone or in combination with one or more of the first through fourth implementations, the second etchant includes a chlorine-containing gas.

In a sixth implementation, alone or in combination with one or more of the first through fifth implementations, a difference between a first etch rate of the second etchant for a material of sidewalls of the recess and a second etch rate of the second etchant for a material of the source/drain region is greater than a difference between a third etch rate of the first etchant for the material of sidewalls of the recess and a fourth etch rate of the first etchant for the material of the source/drain region.

Although FIG. 13 shows example blocks of process 1300, in some implementations, process 1300 includes additional blocks, fewer blocks, different blocks, or differently arranged blocks than those depicted in FIG. 13. Additionally, or alternatively, two or more of the blocks of process 1300 may be performed in parallel.

In this way, a source/drain contact of a nanostructure transistor is formed such that the source/drain contact is recessed within an underlying source/drain region of the nanostructure transistor using a multiple-step etching process. The source/drain contact being recessed within the source/drain region provides a greater amount of surface area for the source/drain contact to contact the source/drain region. This provides for increased contact surface area between the source/drain contact and the source/drain region, and the increased contact surface area provides for reduced contact resistance between the source/drain region and the source/drain contact, because of the less-restricted current flow path between the source/drain region and the source/drain contact. In this way, the reduced contact resistance between the source/drain region and the source/drain contact enables a greater power efficiency to be achieved for the nanostructure transistor and/or enables increased switching speeds to be achieved for the nanostructure transistor, among other examples.

As described in greater detail above, some implementations described herein provide a method. The method includes forming a plurality of nanostructure channels that are arranged in a direction that is approximately perpendicular to a substrate of a semiconductor device. The method includes forming a source/drain region adjacent to the plurality of nanostructure channels. The method includes forming a dielectric layer above the source/drain region. The method includes forming a gate structure that wraps around at least three sides of the plurality of nanostructure channels. The method includes forming a recess through the dielectric layer and into the source/drain region such that a bottom of the recess is at a depth in the semiconductor device that is lower than a top-most nanostructure channel of the plurality of nanostructure channels, and that is approximately equal to or lower than a top surface of a second nanostructure channel of the plurality of nanostructure channels, where the second nanostructure channel is below the top-most nanostructure channel. The method includes forming a source/drain contact in the recess such that the source/drain contact extends into the source/drain region.

As described in greater detail above, some implementations described herein provide a method. The method includes forming a plurality of nanostructure channels that are arranged in a direction that is approximately perpendicular to a substrate of a semiconductor device. The method includes forming a source/drain region adjacent to the plurality of nanostructure channels. The method includes forming a dielectric layer above the source/drain region. The method includes forming a gate structure that wraps around at least three sides of the plurality of nanostructure channels. The method includes performing a first etch operation to form a recess through the dielectric layer and into the source/drain region such that a bottom of the recess is at a first depth in the recess. The method includes performing a second etch operation to increase the recess from the first depth to a second depth that is below a top-most nanostructure channel of the plurality of nanostructure channels. The method includes forming a source/drain contact in the recess such that the source/drain contact extends into the source/drain region.

As described in greater detail above, some implementations described herein provide a semiconductor device. The semiconductor device includes a plurality of nanostructure channels arranged in a first direction in the semiconductor device. The semiconductor device includes a gate structure over the plurality of nanostructure channels that wraps around the plurality of nanostructure channels. The semiconductor device includes a source/drain region adjacent to a side of the gate structure and adjacent to ends of the plurality of nanostructure channels in a second direction that is approximately perpendicular to the first direction. The semiconductor device includes a CESL extending along a sidewall of the gate structure and a top surface of the source/drain region, and an ILD layer over the CESL. The semiconductor device includes a plurality of inner spacers between the source/drain region and the gate structure. The semiconductor device includes a source/drain contact extending through the ILD layer, through the CESL, and into the source/drain region to a depth that is lower than top-most inner spacers of the plurality of inner spacers.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a plurality of nanostructure channels that are arranged in a direction that is approximately perpendicular to a substrate of a semiconductor device;
forming a source/drain region adjacent to the plurality of nanostructure channels;
forming a dielectric layer above the source/drain region;
forming a gate structure that wraps around at least three sides of the plurality of nanostructure channels;
forming a recess through the dielectric layer and into the source/drain region such that a bottom of the recess is at a depth in the semiconductor device that is lower than a top-most nanostructure channel of the plurality of nanostructure channels, and that is approximately equal to or lower than a top surface of a second nanostructure channel of the plurality of nanostructure channels,
wherein the second nanostructure channel is below the top-most nanostructure channel; and
forming a source/drain contact in the recess such that the source/drain contact extends into the source/drain region.

2. The method of claim 1, wherein forming the recess comprises:
forming the recess such that the bottom of the recess is at a depth in the semiconductor device that is approximately equal to or lower than a bottom surface of the second nanostructure channel.

3. The method of claim 1, wherein forming the recess comprises:
forming the recess such that the bottom of the recess is at a depth in the semiconductor device that is approximately equal to or lower than a bottom surface of a bottom-most nanostructure channel of the plurality of nanostructure channels.

4. The method of claim 1, wherein forming the source/drain contact comprises:
forming a metal silicide layer in the recess; and
forming the source/drain contact on the metal silicide layer.

5. The method of claim 4, wherein forming the source/drain region comprises:
forming a first layer of epitaxially-grown material that is in contact with the plurality of nanostructure channels; and
forming a second layer of epitaxially-grown material on the first layer of epitaxially-grown material,
wherein forming the metal silicide layer comprises:
forming the metal silicide layer such that the metal silicide layer is in contact with the second layer of epitaxially-grown material and is spaced apart from the first layer of epitaxially-grown material by the second layer of epitaxially-grown material.

6. The method of claim 5, wherein the first layer of epitaxially-grown material comprises a plurality of non-contiguous portions that are in contact with the plurality of nanostructure channels.

7. The method of claim 5, wherein the first layer of epitaxially-grown material comprises a plurality of contiguous portions that are in contact with the plurality of nanostructure channels.

8. The method of claim 4, wherein forming the source/drain region comprises:
forming a first layer of epitaxially-grown material that is in contact with the plurality of nanostructure channels; and
forming a second layer of epitaxially-grown material on the first layer of epitaxially-grown material,
wherein forming the recess comprises:
forming the recess such that the bottom of the recess extends through the second layer of epitaxially-grown material and into the first layer of epitaxially-grown material, and
wherein forming the metal silicide layer comprises:
forming the metal silicide layer such that first portions of the metal silicide layer are in contact with the second layer of epitaxially-grown material, and such that a second portion of the metal silicide layer is in contact with first layer of epitaxially-grown material.

9. A method, comprising:
forming a plurality of nanostructure channels that are arranged in a direction that is approximately perpendicular to a substrate of a semiconductor device;
forming a source/drain region adjacent to the plurality of nanostructure channels;
forming a dielectric layer above the source/drain region;
forming a gate structure that wraps around at least three sides of the plurality of nanostructure channels;
performing a first etch operation to form a recess through the dielectric layer and into the source/drain region such that a bottom of the recess is at a first depth in the recess;
performing a second etch operation to increase the recess from the first depth to a second depth that is below a top-most nanostructure channel of the plurality of nanostructure channels; and
forming a source/drain contact in the recess such that the source/drain contact extends into the source/drain region.

10. The method of claim 9, further comprising:
forming, after the first etch operation and prior to the second etch operation, a protective liner on sidewalls of the recess and on a top of the source/drain region in the recess; and
performing, after the first etch operation and prior to the second etch operation, a third etch operation to etch through the protective liner to expose the top of the source/drain region through the recess.

11. The method of claim 10, wherein performing the second etch operation comprises:
performing the second etch operation while the protective liner is on the sidewalls of the recess.

12. The method of claim 9, wherein performing the first etch operation comprises:
performing the first etch operation using a first etchant; and
wherein performing the second etch operation comprises:
performing the second etch operation using a second etchant,
wherein the first etchant and the second etchant are different etchants.

13. The method of claim 12, wherein a first etch rate of the second etchant for a material of sidewalls of the recess is less than a second etch rate of the second etchant for a material of the source/drain region.

14. The method of claim 12, wherein the second etchant comprises a chlorine-containing gas.

15. The method of claim 12, wherein a difference between a first etch rate of the second etchant for a material of sidewalls of the recess and a second etch rate of the second etchant for a material of the source/drain region is greater than a difference between a third etch rate of the first etchant for the material of sidewalls of the recess and a fourth etch rate of the first etchant for the material of the source/drain region.

16. A semiconductor device, comprising:
a plurality of nanostructure channels arranged in a first direction in the semiconductor device;
a gate structure over the plurality of nanostructure channels and that wraps around the plurality of nanostructure channels;
a source/drain region adjacent to a side of the gate structure and adjacent to ends of the plurality of nanostructure channels in a second direction that is approximately perpendicular to the first direction;
a contact etch stop layer (CESL) extending along a sidewall of the gate structure and a top surface of the source/drain region;
an interlayer dielectric (ILD) layer over the CESL;
a plurality of inner spacers between the source/drain region and the gate structure; and
a source/drain contact extending through the ILD layer, through the CESL, and into the source/drain region to a depth is lower than top-most inner spacers of the plurality of inner spacers.

17. The semiconductor device of claim 16, wherein the source/drain region comprises:
a first epitaxial region surrounding a bottom of the source/drain contact; and
a plurality of non-contiguous second epitaxial regions between the first epitaxial region and the plurality of nanostructure channels.

18. The semiconductor device of claim 16, wherein the source/drain region comprises:
a first epitaxial region surrounding a bottom of the source/drain contact; and
a second epitaxial region between the first epitaxial region and the plurality of nanostructure channels, and between the first epitaxial region and the plurality of inner spacers.

19. The semiconductor device of claim 16, wherein the source/drain region comprises:
a first epitaxial region surrounding sidewalls of the source/drain contact; and
a second epitaxial region between the first epitaxial region and the plurality of nanostructure channels,
wherein a bottom of the source/drain contact extends into the second epitaxial region.

20. The semiconductor device of claim 16, further comprising:
a metal silicide layer between the source/drain contact and the source/drain region,
wherein the metal silicide layer extends from a top of the source/drain region to a bottom of the source/drain contact.
